(19) United States
(12) Patent Application Publication
(10) Pub. No.: US 2021/0135064 A1
(43) Pub. Date: May 6, 2021

(54) DISPLAY DEVICE AND MANUFACTURING METHOD OF DISPLAY DEVICE

(71) Applicant: Sharp Fukuyama Semiconductor Co., Ltd., Fukuyama City (JP)

(72) Inventor: TOSHIYA ISHIO, Fukuyama City (JP)

(21) Appl. No.: 17/083,800

(22) Filed: Oct. 29, 2020

(30) Foreign Application Priority Data
Oct. 31, 2019 (JP) 2019-199002

(51) Int. Cl. H01L 33/50; H01L 25/075; H01L 33/58; H01L 33/62; H01L 33/00

(52) U.S. Cl. CPC H01L 33/504; H01L 25/0753; H01L 33/58; H01L 2933/0058; H01L 33/0095; H01L 2933/0041; H01L 2933/0066; H01L 33/62

(57) ABSTRACT

A display device includes a plurality of light-emitting elements, color conversion layers configured to convert a color of light emitted from the plurality of light-emitting elements, and a partition configured to separate a region provided with each of the color conversion layers, wherein the partition is formed of an inorganic material having a light-shielding property.

### CROSS-REFERENCE TO RELATED APPLICATION

The present application claims priority from Japanese Application JP2019-199002, the content of which is hereby incorporated by reference into this application.

### BACKGROUND OF THE INVENTION

### 1. Field of the Invention

An aspect of the present disclosure relates to a display device including a color conversion layer and a method for manufacturing the display device.

### 2. Description of the Related Art

In the related art, various techniques have been proposed for suppressing reduction in color purity in display devices. For example, JP 2009-252406 A (hereinafter, referred to as PTL 1) discloses a color conversion filter in which a color conversion layer for a color filter is formed in a first layer, and a color conversion layer including a color conversion pigment is formed in a second layer. In the color conversion filter, the color conversion layer in the first layer is partitioned by a black matrix on a transparent substrate, and a bank layer serving as a side wall of the color conversion layer is formed, instead of the black matrix, in the color conversion layer in the second layer. The bank layer is formed of a transparent resin or a transparent inorganic material such as SiOx, SiNx, SiNxOy, AlOx, TiOx, TaOx, and ZnOx. The bank layer has a thickness of 3 μm, and the color conversion layer including the color conversion pigment and being formed in a region surrounded by the bank layer has a thickness of 2 μm or less. With the configuration and the like described above, the color conversion filter disclosed in PTL 1 suppresses reduction in intensity and color purity of emitted light.

### SUMMARY OF THE INVENTION

However, as described above, a transparent resin or a transparent inorganic material is employed for the bank layer described in PTL 1. As a result, light leaks from adjacent pixels or subpixels in a traverse direction (a direction substantially perpendicular to a direction in which each layer is layered, that is, a horizontal direction) of the color conversion layer including the color conversion pigment, which results in a problem of crosstalk of light.

In addition, in a type of display device utilizing self-emitting elements as described above, for example, if these elements are to be used as a mobile display device having a size of 50 mm square or smaller, a pixel size or a subpixel size becomes very small. Therefore, from the viewpoint of the size, it is difficult to arrange light emitting diode (LED) packages to achieve a mobile display device. To achieve a mobile display device having a size of 50 mm square or smaller, light-emitting elements emitting blue light, blue-purple light, and ultraviolet light are arranged, and the light needs to be converted into desired color light in the color conversion layer.

However, a type of color conversion layer that changes the wavelength of light by a phosphor or a quantum dot phosphor needs to have a thickness of 10 μm or greater if used alone, or 4 μm or greater even if used in combination with a color filter. Therefore, if a black matrix having a thickness of 1 μm or less typically employed in liquid crystal televisions (TVs) or the like is employed, light passes through the color conversion layer in the traverse direction, causing crosstalk of the light. In mobile display devices, particularly, in mobile display devices that are not more than 50 mm even in the longer direction, there is a huge problem of susceptibility to crosstalk of light because of a narrow gap between pixels or between subpixels.

An aspect of the present disclosure has been made in view of the above problems in the related art, and an object thereof is to realize a display device in which crosstalk of light is not easily generated.

To solve the above problems, a display device according to an aspect of the present disclosure includes a plurality of light-emitting elements, color conversion layers that convert a color of light emitted from the plurality of light-emitting elements, and a partition that separates a region provided with each of the color conversion layers, the partition being formed of an inorganic material having a light-shielding property.

To solve the above problems, a method for manufacturing a display device according to an aspect of the present disclosure includes a partition providing step of providing, in a display device emitting monochrome light and in which a plurality of light-emitting elements are arranged, a space separated by a partition formed of an inorganic material having a light-shielding property, to substantially match an arrangement of each of the plurality of light-emitting elements, and a color conversion layer providing step of providing, in the space separated by the partition, color conversion layers that convert a color of light emitted from the plurality of light-emitting elements.

According to an aspect of the present disclosure, it is possible to realize a display device in which crosstalk of light is not easily generated.

### BRIEF DESCRIPTION OF THE DRAWINGS

FIG. 1 provides a schematic longitudinal cross-sectional view of a display device according to a first embodiment of the present disclosure, which is indicated with L1, and also provides a plan view of the display device, which is indicated with L2.

FIG. 2 is a detailed view of part A in L1 of FIG. 1.

FIG. 3 is a schematic longitudinal cross-sectional view illustrating an example of a shape of a partition of the display device.

FIG. 4 is a schematic cross-sectional view illustrating an example of a manufacturing process of the display device.

FIG. 5 is a schematic cross-sectional view illustrating an example of the manufacturing process of the display device, and is a diagram illustrating a continuation of FIG. 4.

FIG. 6 is a schematic cross-sectional view illustrating another example of the manufacturing process of the display device.

FIG. 7 is a schematic cross-sectional view illustrating another example of the manufacturing process of the display device, and is a diagram illustrating a continuation of FIG. 6.

FIG. 8 is a detailed view of part A in L1 of FIG. 1, and is a schematic longitudinal cross-sectional view illustrating a first modification of the display device.

FIG. 9 is a schematic cross-sectional view illustrating an example of a manufacturing process according to the first modification of the display device.

FIG. 10 is a schematic cross-sectional view illustrating an example of the manufacturing process according to the first modification of the display device, and is a diagram illustrating a continuation of FIG. 9.

FIG. 11 is a detailed view of part A in L1 of FIG. 1, and is a schematic longitudinal cross-sectional view illustrating a second modification of the display device.

FIG. 12 is a schematic cross-sectional view illustrating an example of a manufacturing process according to the second modification of the display device.

FIG. 13 is a schematic cross-sectional view illustrating an example of the manufacturing process according to the second modification of the display device, and is a diagram illustrating a continuation of FIG. 12.

FIG. 14 provides a plan view illustrating an example of an arrangement of slits formed in the partition, which is indicated with K1, and a plan view illustrating another example of the arrangement of slits formed in the partition, which is indicated with K2.

FIG. 15 provides a schematic longitudinal cross-sectional view of a display device according to a second embodiment of the disclosure, which is indicated with L11, and a plan view of the display device, which is indicated with L12.

FIG. 16 is a detailed view of part B in L11 of FIG. 15.

FIG. 17 is a schematic cross-sectional view illustrating an example of a manufacturing process of the display device.

FIG. 18 is a schematic cross-sectional view illustrating an example of the manufacturing process of the display device, and is a diagram illustrating a continuation of FIG. 17.

FIG. 19 is a detailed view of part B in L11 of FIG. 15, and is a schematic longitudinal cross-sectional view illustrating a first modification of the display device.

FIG. 20 is a schematic cross-sectional view illustrating an example of a manufacturing process according to the first modification of the display device.

FIG. 21 is a schematic cross-sectional view illustrating an example of the manufacturing process according to the first modification of the display device, and is a diagram illustrating a continuation of FIG. 20.

FIG. 22 is a detailed view of part B in L11 of FIG. 15, and is a schematic longitudinal cross-sectional view illustrating a second modification of the display device.

FIG. 23 is a schematic cross-sectional view illustrating an example of a manufacturing process according to the second modification of the display device.

FIG. 24 is a schematic cross-sectional view illustrating an example of the manufacturing process according to the second modification of the display device, and is a diagram illustrating a continuation of FIG. 23.

FIG. 25 is a schematic longitudinal cross-sectional view illustrating a typical color conversion layer employed in a liquid crystal display device or the like in the related art.

### DETAILED DESCRIPTION OF THE INVENTION

### First Embodiment

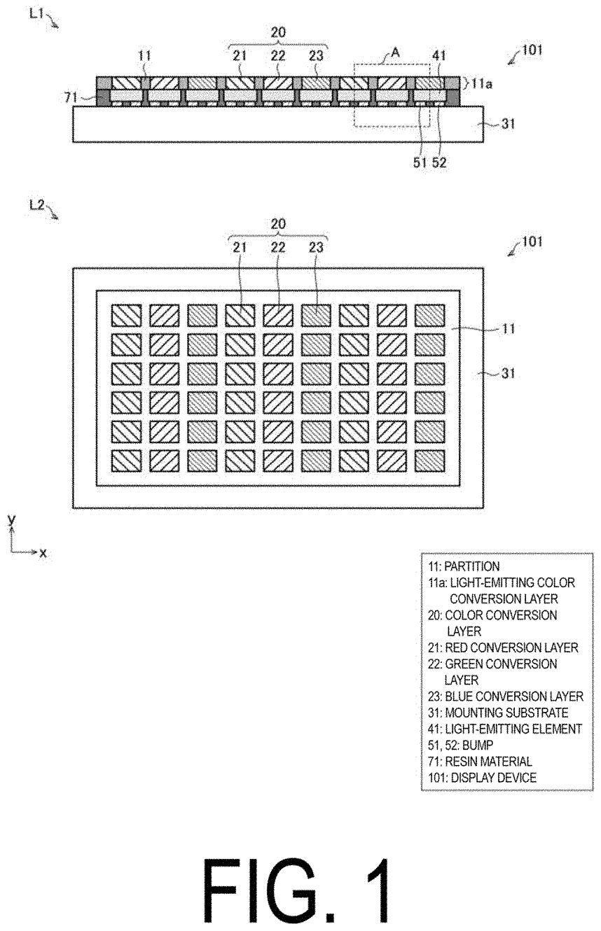

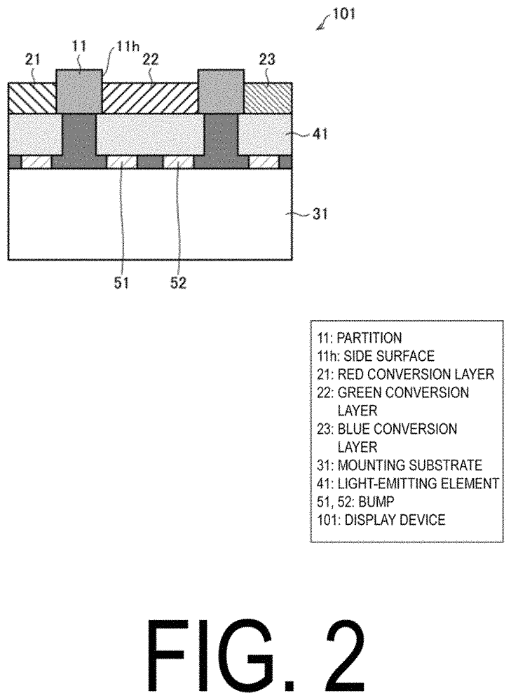

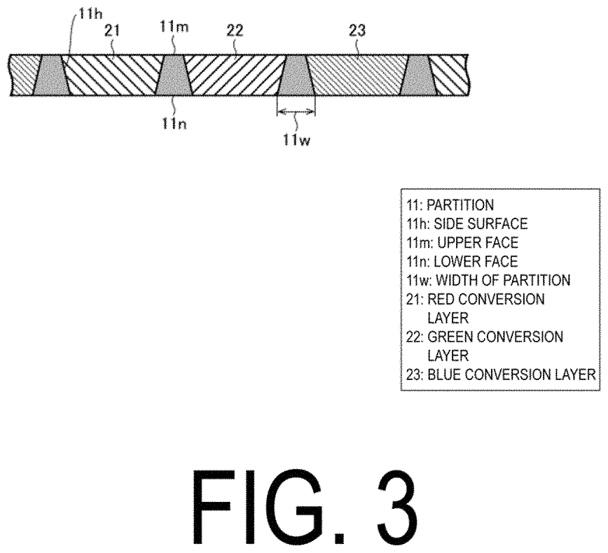

An embodiment of the present disclosure will be described in detail below with reference to FIGS. 1 to 3. L1 in FIG. 1 is a schematic longitudinal cross-sectional view of a display device 101 according to a first embodiment of the present disclosure, and L2 in FIG. 1 is a plan view of the display device 101. FIG. 2 is a detailed view of part A in L1 of FIG. 1. FIG. 3 is a schematic longitudinal cross-sectional view illustrating an example of a shape of a partition 11 of the display device 101.

### Configuration of Display Device

As illustrated in FIG. 1 and FIG. 2, the display device 101 includes a partition 11, color conversion layers 20, a mounting substrate 31, and a light-emitting element 41. The display device 101 can be suitably utilized as a mobile display device.

### Mounting Substrate

A large-scale integration (LSI) substrate including at least one of a drive circuit and a control circuit of the light-emitting element 41 can be employed for the mounting substrate 31. If the LSI substrate is employed, it is possible to reduce the size of the display device 101, and thus, the LSI substrate is suitable for the display device 101 for mobile applications. The mounting substrate 31 may be provided with a wiring or the like, and the light-emitting element 41 may be driven and controlled from outside of the mounting substrate 31.

### Light-Emitting Element

A plurality of the light-emitting elements 41 are mounted on the mounting substrate 31. Light emitting diode (LED) elements, for example, may be employed for the light-emitting elements 41. Extremely small LED elements, for example, having a long side of 10 μm or less are employed. The light-emitting elements 41 are singulated to serve as a light-emitting element chip so as to include one or more of the light-emitting elements 41 and are mounted on the mounting substrate 31. If the light-emitting elements 41 are singulated into light-emitting element chips, it is possible to prevent light of each of the light-emitting elements 41 from leaking out in the traverse direction (horizontal direction). The light-emitting element chip is not limited to the above, and a substrate may be employed in which light-emitting element chips are connected and integrated throughout the entire display device 101.

The mounting substrate 31 and each of the light-emitting elements 41 are electrically connected via a bump 51 and a bump 52. Each of the light-emitting elements 41 is driven and controlled by an LSI substrate serving as the mounting substrate 31 via the bumps 51 and 52. The bumps 51 and 52 electrically connect the cathode electrode and the anode electrode of the light-emitting element 41, and the electrode of the mounting substrate 31. The cathode electrode and the anode electrode of the light-emitting element 41 may have a structure in which the bumps 51 and 52 are interchanged. In other words, for example, either one of the bump 51 or the bump 52 may be the cathode electrode, and the interchange of the cathode electrode and the anode electrode of the light-emitting element 41 can be handled by interchanging the electrode arrangement of the mounting substrate 31.

Electrode pads are provided on a periphery of the mounting substrate 31 (not illustrated), which makes it possible to supply data for images, a power supply voltage for the LSI serving as the mounting substrate 31, and the like from the outside to the mounting substrate 31. However, data for images may be created inside the LSI substrate.

Each of the light-emitting elements 41 is mounted on the mounting substrate 31 while maintaining an array state when prepared as a semiconductor wafer. Here, the array state refers to a state in which the relative coordinates of each of the light-emitting elements 41 of the semiconductor wafer are maintained, in other words, a state in which each of the light-emitting elements 41 is arranged at a constant interval. A region between the light-emitting elements 41 is divided by dry etching or the like, and each of the light-emitting elements 41 is mounted on the mounting substrate 31 while maintaining a state in which the relative coordinates of the light-emitting elements 41 are maintained. As a result, as compared with a case in which the light-emitting elements 41 are mounted one by one on the mounting substrate 31 by a pick and place method, it is possible to reduce a gap between the light-emitting elements 41, and also shorten the time taken for mounting all the light-emitting elements 41.

A resin material 71 is provided between the light-emitting elements 41 and the mounting substrate 31, between the light-emitting elements 41, in a periphery of the bumps 51 and 52, and the like to reinforce a joint part between the light-emitting elements 41 and the bumps 51 and 52. The resin material 71 is formed of a material through which light does not easily pass, for example, a black resin material.

### Color Conversion Layer

Each of the color conversion layers 20 converts a color of light emitted from the light-emitting elements 41. The color conversion layer 20 includes a red conversion layer 21, a green conversion layer 22, and a blue conversion layer 23. A phosphor or a quantum dot phosphor serving as the color conversion layer 20 is provided on each of the light-emitting elements 41, and a color filter or the like is further provided, as necessary.

### Case Where Light-Emitting Element Emitting Blue Light is Employed

If the light-emitting element 41 that emits blue light is employed, for example, a phosphor or a quantum dot phosphor that converts blue color into red color is provided for the red conversion layer 21. A phosphor or a quantum dot phosphor that converts blue color into green color is provided for the green conversion layer 22. Either nothing or a transparent resin is provided at the position of the blue conversion layer 23 for the blue conversion layer 23. If a transparent resin is provided for the blue conversion layer 23, the light extraction efficiency improves as compared to a case where nothing is provided at the position of the blue conversion layer 23.

A red color filter may be further provided on the phosphor or the quantum dot phosphor for the red conversion layer 21. Similarly, a green color filter may be further provided on the phosphor or the quantum dot phosphor for the green conversion layer 22. A transparent resin not containing a phosphor or a quantum dot phosphor may be provided in a region where a phosphor or a quantum dot phosphor is not provided, and a blue color filter may be further provided for the blue conversion layer 23. If only a phosphor or a quantum dot phosphor is provided for the color conversion layer 20, the thickness of the color conversion layer 20 is required to be 10 μm or greater, however if the color conversion layer 20 is used in conjunction with a color filter, it is possible to reduce the thickness of the color conversion layer 20.

A yellow phosphor that converts the entire blue light of the light-emitting element 41 into white may be provided, and in addition, a red color filter may be provided for the red conversion layer 21, a green color filter may be provided for the green conversion layer 22, and a blue color filter may be provided for the blue conversion layer 23. If a mixture of a green phosphor and a red phosphor is used instead of a yellow phosphor, color development is better than when a yellow phosphor is provided.

In the blue conversion layer 23, a blue color filter may be provided directly without a yellow phosphor or a red and blue mixed phosphor, and a blue color filter may be provided on the transparent resin. Furthermore, the blue conversion layer 23 may not include a blue color filter but be configured to emit unfiltered light from the light-emitting element 41 that emits blue light. The blue conversion layer 23, which does not perform the color conversion in this case, is still referred to as the blue conversion layer 23 in the present embodiment. However, if short wavelength light having a negative impact on visual acuity is emitted from the light-emitting elements 41, it is preferable to employ a blue color filter. This is because the blue color filter cuts light in a short wavelength range.

### Case Where Light-Emitting Element Emitting Light Other Than Blue Light is Employed

The light-emitting element 41 that outputs purple light, blue-purple light, or ultraviolet light may be employed. In this case, a phosphor or a quantum dot phosphor emitting red, green, and blue light is provided on each of the light-emitting elements 41. In this case as well, a color filter may be further provided. However, if ultraviolet light is mixed, there is a possibility of a negative impact on visual acuity, and thus, if ultraviolet light is mixed, it is preferable to employ the light-emitting element 41 in combination with a color filter, or employ a light-emitting element 41 that outputs blue light.

In the display device 101, if a color filter is provided in the color conversion layer 20, an amount of light that can be transmitted decreases, resulting in a darker color than when a color filter is not used, but the color reproducibility improves. If it is possible to provide a phosphor film having a thickness of, for example, approximately 10 μm or greater for the color conversion layer 20, the color reproducibility is good even without a color filter. In addition, if phosphor particles dispersed in a transparent resin are used as a binder, it is easy to fix the phosphor film on the light-emitting element 41. The color reproducibility improves if a quantum dot phosphor is employed instead of a phosphor.

While the display device 101 functions as a monochrome display, if a phosphor, a quantum dot phosphor, or a color filter of each color is appropriately combined, the display device 101 can also function as a color display.

### Partition

The partition 11 separates a region where each of the color conversion layers 20 is provided. In other words, the color conversion layer 20 is surrounded by the partition 11. The partition 11 is formed of an inorganic material having a light-shielding property. The color conversion layer 20 is surrounded by the partition 11 formed of an inorganic material having a light-shielding property, and thus, for example, light emitted from adjacent pixels or subpixels does not easily mix. As a result, it is possible to reduce crosstalk of light. Here, a subpixel indicates a combination of the light-emitting elements 41 that emit red monochrome light, green monochrome light, and blue monochrome light, and the color conversion layer 20, and a pixel indicates one set of subpixels emitting red, green, and blue light. The color conversion layer 20 and the partition 11 constitute a light-emitting color conversion layer 11a.

### Material of Partition

The partition 11 is formed of an inorganic material having a light-shielding property. It is preferable to employ a material having metallic luster for the inorganic material. If a material having metallic luster, such as a metallic material (conductive material) or a semi-metallic material (conductive material) is employed for the material of the partition 11, the partition 11 reflects light from the color conversion layer 20. This improves the extraction efficiency of light of each pixel or subpixel.

The material of the partition 11 may be a material exhibiting a metallic luster, such as aluminum, an aluminum alloy, copper, a copper alloy, gold, a gold alloy, an iron-nickel alloy such as 42 alloy, silicon, or germanium. Furthermore, a material to which various elements are added may also be employed as long as the material has a metallic luster. Metallic materials are more likely to reflect light than semi-metallic materials, and even among metals, silver or aluminum, or a material including silver or aluminum as a main component has more light reflectivity. Note that if a silver-based material is employed, ion migration is likely to occur. Therefore, if a voltage is to be applied to the partition 11 or the periphery of the partition 11, an aluminum or aluminum-based alloy is preferably employed.

The surface of the semi-metallic material may be coated with a metallic film (conductive film). As a result, the light extraction efficiency further improves than the surface of the semi-metallic material, and additionally, the electrical conductivity and thermal conductivity are improved. However, if the surface of the semi-metallic material is coated with a metallic film, the process may be complex, and thus, it is desirable to appropriately determine whether to coat the surface in consideration of cost effectiveness.

### Height and Width of Partition

If the color conversion layer 20 includes a combination of a phosphor or a quantum dot phosphor and a color filter, the height of the partition 11 together with the thickness of a phosphor layer of the phosphor or the quantum dot phosphor combined with the thickness of the color filter layer is required to be 4 μm or greater. If a color filter is not employed for each of the color conversion layers 20, the height of the partition 11 is required to be from 5 μm to 10 μm, or greater.

In a mobile display device such as a wrist-watch display device, the size of the display is approximately 30 mm to 50 mm in the longer direction and 20 mm to 50 mm in the shorter direction. In the display having such a size, 1920×1080 pixels are formed for a full high definition (HD) image quality, and further, 5760 subpixels that is three times of the number of the pixels are formed in the longer direction, for a color display.

For example, if 5760 subpixels are formed within 50 mm in the longer direction, a pitch between subpixels is approximately 8.7 μm. Actually, a display includes a subpixel region and a region between subpixels, that is, a space region in which subpixels do not exist. For example, if a subpixel pitch is 8.7 μm, a subpixel is 5.7 μm, and the space region is 3 μm. If the size of the display of a mobile display device is 30 mm in the longer direction, the pitch between subpixels is approximately 5.2 μm, and in this case, the space region is 2 μm or less. In consideration of the display quality of the display device, it is necessary to narrow down an unilluminated portion, and thus, a smaller space region is preferable.

In augmented reality (AR) eyewear applications, it is necessary to mount a display device to eyewear, and thus, the size of the display is required to be approximately 15 mm at the most in the longer direction. If the size in the longer direction is 15 mm, in the color full HD image quality, the pitch between subpixels is approximately 2.6 μm, and the space region is required to be 1 μm or less, for example. Even in the high definition (HD) image quality (1280×720 pixels), 3840 subpixels are required in the longer direction, and the pitch between subpixels is approximately 3.9 μm. Also, in the standard definition (SD) image quality (720×480 pixels), 2160 subpixels are required in the longer direction, and the pitch between subpixels is approximately 6.9 μm. Therefore, in AR eyewear applications, even in the case of the HD image quality and the SD image quality, the space region is required to be, for example, 3 μm or less.

Thus, in mobile display devices, particularly, in mobile displays having the size of 50 mm or less even in the longer direction, the space region is required to be approximately 3 μm or less. The width of the partition 11 (a width 11w of a lower face 11n of the partition 11) is preferably equal to or greater than the width of the space region, and is therefore required to be 4 μm or less. The partition 11 is required to have an aspect ratio (height/width) of 1 or greater.

In the present embodiment, if a color filter is employed in combination, the space region between subpixels is 1 μm, the width 11w of the partition 11 is 2 μm, and the height of the partition 11 is 4 μm or greater. If a color filter is not employed in combination, the width 11w of the partition 11 is 2 μm, and the height of the partition 11 is 10 μm or greater.

However, if the space region between subpixels is less than 1 μm, for example, 0.5 μm, the width 11w of the partition 11 may be 1 μm or greater. Thus, the reason for keeping the width 11w of the partition 11 larger than the space region between subpixels is because of at least one, preferably two, and more preferably three effects out of the following three contents are obtained. The first effect is an effect for preventing light emitted from a certain light-emitting element 41 (subpixel) as a starting point from leaking to other subpixels through the color conversion layer 20 and the resin material 71. The second effect is an effect for releasing heat generated from the light-emitting elements 41 as a result of the light-emitting elements 41 and the partition 11 coming in contact with each other. The third effect is an effect for utilizing the partition 11 as a conductor, as described later.

### Side Surface of Partition

To take advantage of the properties of a material having metallic luster, the surface roughness of a side surface 11h of the partition 11 (see FIG. 3) is desired to be smoother than an upper face 11m of the partition 11 (the surface opposite to the light-emitting element 41 side). As a result, the side surface 11h easily reflects light emitted by the light-emitting elements 41. In contrast, if the surface roughness of the upper face 11m of the partition 11 is rougher than that of the side surface 11h, reflection of light is suppressed to improve the visibility of display in the display device 101. A film for preventing reflection may be provided on the upper face 11m. The film may include a black resin, for example. If the surface roughness of the upper face 11m increases, the adhesive force with the film of resin or the like improves.

In addition, if the side surface 11h has metallic luster, as illustrated in FIG. 3, in the red conversion layer 21, the green conversion layer 22, or the blue conversion layer 23, the light extraction efficiency of the side surface 11h improves when the side surface 11h on the side of the upper face 11m is wider than when both the upper face 11m and the lower face 11n are of the same size. In other words, the light extraction efficiency improves when the side surface 11h is inclined to open toward the upper face 11m from the lower face 11n than when the side surface 11h is upright in a substantially vertical direction without an inclination.

### Example of Manufacturing Method

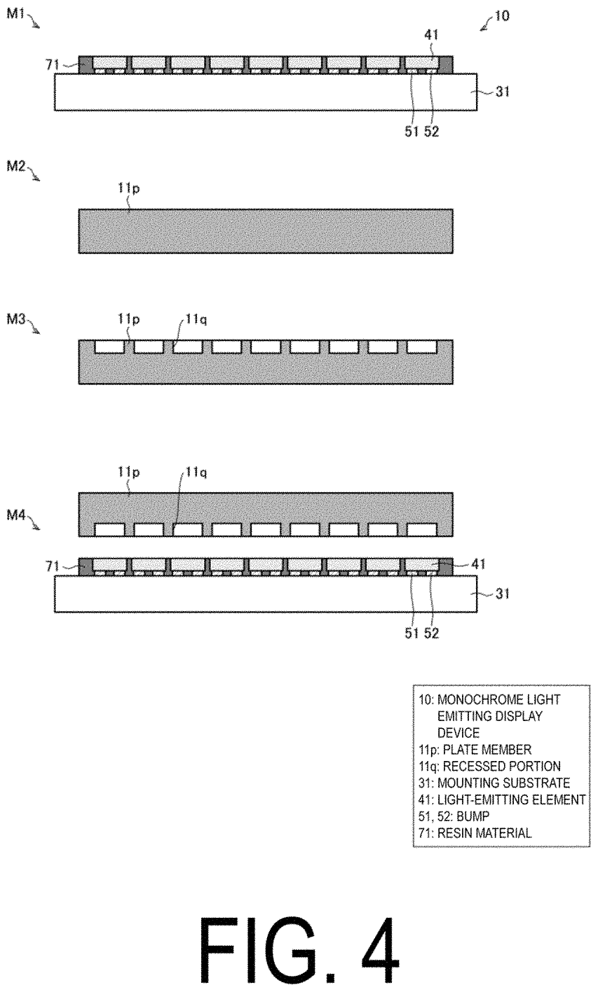

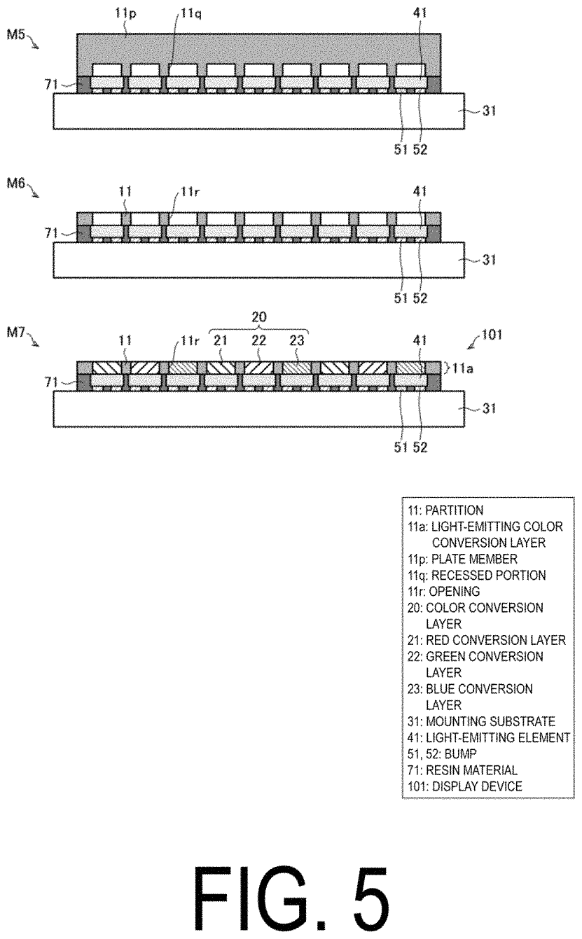

An example of a method for manufacturing the display device 101 will be described with reference to steps M1 to M7 of FIGS. 4 and 5. FIGS. 4 and 5 are schematic cross-sectional views illustrating an example of a manufacturing process of the display device 101.

Firstly, as illustrated in step M1 of FIG. 4, a mobile high definition monochrome light emitting display device (hereinafter, referred to as a monochrome light emitting display device) 10 is prepared. Examples of the mobile device include display devices such as tablet terminals and smart phones, however, in the present embodiment, a device having even a long side of 50 mm or less (50×50 mm or less) is employed. Any display device being a monochrome light emitting display device having a long side of 50 mm or less may be employed, however, any such display device also includes a display device mounted to AR eyewear, and thus, an ultra-small monochrome light emitting display device 10 having even a long side of a display of approximately 15 mm or less will be described.

In the monochrome light emitting display device 10, the light-emitting elements 41 are arranged in an array and mounted on an LSI substrate being the mounting substrate 31 via the two bumps 51 and 52. The number of the bumps 51 and 52 connected to either the cathode electrode or the anode electrode of the light-emitting elements 41 need not be the same, and either the bump 51 or the bump 52 may be provided as a common electrode bundling together the plurality of light-emitting elements 41.

Next, a step of preparing the partition 11 for separately providing each of the color conversion layers 20 will be described. As illustrated in step M2 of FIG. 4, a plate member 11p formed of an inorganic material having a light-shielding property is prepared. The plate member 11p is the plate member 11p for forming the partition 11 for the color conversion layer 20 (the red conversion layer 21, the green conversion layer 22, and the blue conversion layer 23) provided in the monochrome light emitting display device 10.

If a metallic or semi-metallic material is employed for the plate member 11p, the partition 11 has a light-shielding property. It is preferable to employ a silicon wafer for the plate member 11p to facilitate processing. For example, in step M2 of FIG. 4, a silicon wafer having a thickness of 100 μm or greater to be readily handled is prepared as the plate member 11p. Specifically, if, for example, an 8-inch wafer is employed, a silicon wafer having a thickness of 725 μm is typically prepared. However, as long as the plate member 11p is easily handled, the plate member 11p may be 100 μm or less in thickness.

Next, as illustrated in step M3 of FIG. 4, a recessed portion 11q is formed in the plate member 11p to substantially match a pitch of subpixels of the display device 101. Specifically, a device for Deep RIE being a type of reactive ion etching (RIE) is used to form the recessed portion 11q to substantially match the pitch of the light-emitting elements 41 by dry etching from the surface side (glossy surface side) of the silicon wafer.

In the present embodiment, the recessed portion 11q is formed to leave a width of 2 μm for the partition 11. If the thickness of the color conversion layer 20 is 4 μm, a recessed portion 11q that is deeper than 4 μm, for example, having a depth of 6 μm or greater is formed. If the thickness of the color conversion layer 20 is, for example, 10 μm, the recessed portion 11q having a depth of 12 μm or greater is formed. Thus, the recessed portion 11q is formed to be slightly deeper than the thickness of the color conversion layer 20.

Next, as illustrated in step M4 of FIG. 4 and step M5 of FIG. 5, the monochrome light emitting display device 10 and the plate member 11p are bonded to substantially match subpixels of the monochrome light emitting display device 10 prepared in advance and the recessed portion 11q. The bonding employs an existing bonding method. The monochrome light emitting display device 10 and the plate member 11p may be bonded through a resin material, or the plate member 11p and the light-emitting elements 41 may be bonded directly.

An example of the bonding through a resin material includes bonding through a photosensitive resin patterned by photolithography. The patterned photosensitive resin is used as a mask when the recessed portion 11q is provided in the silicon wafer by dry etching. Specifically, as a result of development, the photosensitive resin employed in providing the recessed portion 11q is removed from a region of the recessed portion 11q and remains in a region between the recessed portions 11q. Thus, it is possible to bond the monochrome light emitting display device 10 and the plate member 11p by thermocompression bonding through the photosensitive resin remaining as a result of development. In other words, the photosensitive resin used as the mask in forming the recessed portion 11q by dry etching is further utilized as an adhesive material between the monochrome light emitting display device 10 and the plate member 11p.

Other methods may be employed as described in the following (1) to (5).

(1) A photosensitive resin is applied on the monochrome light emitting display device 10, is subjected to thin spin coating, and is dried. Thereafter, a pattern is formed so that the photosensitive resin is removed from the light-emitting elements 41 serving as the subpixels by photolithography, and the photosensitive resin is left in the space region between the subpixels, and then the monochrome light emitting display device 10 and the plate member 11p are bonded together.

(2) A photosensitive resin is applied on the monochrome light emitting display device 10, is subjected to thin spin coating, and then the plate member 11p in which the recessed portion 11q is formed is affixed on the monochrome light emitting display device 10 to substantially match the recessed portion 11q and the subpixel region. In this case, the photosensitive resin applied to the surface of the light-emitting element 41 is removed in a subsequent step (in step M6 of FIG. 5). Specifically, in step M6 of FIG. 5, the plate member 11p provided with the recessed portion 11q is thinned to a height required for the partition 11. For example, the recessed portion 11q having a depth of 6 μm is thinned up to a required height of 4 μm of the partition 11. At this time, the recessed portion 11q pierces through and the photosensitive resin applied on the surface of the light-emitting elements 41 appears, and thus, if the photosensitive resin is irradiated with light from the plate member 11p side to react the photosensitive resin and is developed, the photosensitive resin applied on the surface of the light-emitting elements 41 is removed. The photosensitive resin applied to the surface of the light-emitting element 41 may also be removed by dry etching in step M6 of FIG. 5. Thus, if being removed by dry etching, the resin need not necessarily be a photosensitive resin. Furthermore, dry etching may be omitted if a transparent resin material is used for bonding.

(3) An inkjet device is used to apply the adhesive resin to the plate member 11p or the space region between the subpixels of the monochrome light emitting display device 10, and bond together the monochrome light emitting display device 10 and the plate member 11p.

(4) If the light-emitting elements 41 are a GaN-based material and the plate member 11p is a silicon material, the monochrome light emitting display device 10 and the plate member 11p may be directly bonded. If the monochrome light emitting display device 10 and the plate member 11p are processed so that the arithmetic mean roughness Ra of both the monochrome light emitting display device 10 and the plate member 11p is, for example, 1 nm or less, and are also subjected to the surface activation process, the monochrome light emitting display device 10 and the plate member 11p can be directly affixed to each other at a temperature ranging from the ambient temperature to approximately 200° C.

(5) If a metallic film is provided on the light-emitting elements 41, and a metallic film is provided on the bonding surface side of a silicon material as the plate member 11p, both the light-emitting elements 41 and the plate member 11p are bonded together. If the metallic film is a material having bondability with the silicon material, a metallic film may not be provided on the silicon material surface. If the light-emitting elements 41 and the partition 11 are bonded using a metallic material, the metallic material needs to be removed by dry etching or the like to substantially match an opening 11r described later.

Next, as illustrated in step M6 of FIG. 5, the opening 11r (space) separated by the partition 11 formed of an inorganic material having a light-shielding property is formed in the plate member 11p. In other words, the monochrome light emitting display device 10 in which the plurality of light-emitting elements 41 are arranged is provided with the opening 11r separated by the partition 11 formed of an inorganic material having a light-shielding property to substantially match the arrangement of each of the light-emitting elements 41 (partition providing step).

Specifically, the plate member 11p is thinned by subjecting the plate member 11p to mechanical grinding, etching, or the like, thereby forming the opening 11r. The etching process is preferably dry etching. The plate member 11p is etched to form the opening 11r such that the depth of the opening 11r substantially matches the required height of the partition 11. Even if a plurality of light-emitting element chips including a plurality of light-emitting elements 41 are arranged on the mounting substrate 31, the opening 11r (space) surrounded by the partition 11 is provided to substantially match each one of the light-emitting elements 41.

Thereafter, as illustrated in step M7 of FIG. 5, the color conversion layer 20 that converts a color of light emitted from the light-emitting elements 41 is provided in the opening 11r separated by the partition 11 (color conversion layer providing step). Specifically, a resin material containing a phosphor or a quantum dot phosphor, and a resinous color filter material are applied in the opening 11r by an inkjet device, and are cured by light or heat to provide the color conversion layer (the red conversion layer 21, the green conversion layer 22, and the blue conversion layer 23). Although photolithography may be employed to provide the color conversion layer 20, if an inkjet device is employed to apply the resin material, it is possible to reduce a waste of a phosphor or quantum dot phosphor material.

The configuration of the color conversion layer 20 is as described earlier. If the surface roughness of the upper face of the partition 11 increases through mechanical grinding or the like, light reflected on the surface of the partition 11 can be suppressed. In addition, if a black resin is provided on the upper face of the partition 11, reflection of ambient light can be suppressed.

### Other Examples of Manufacturing Method

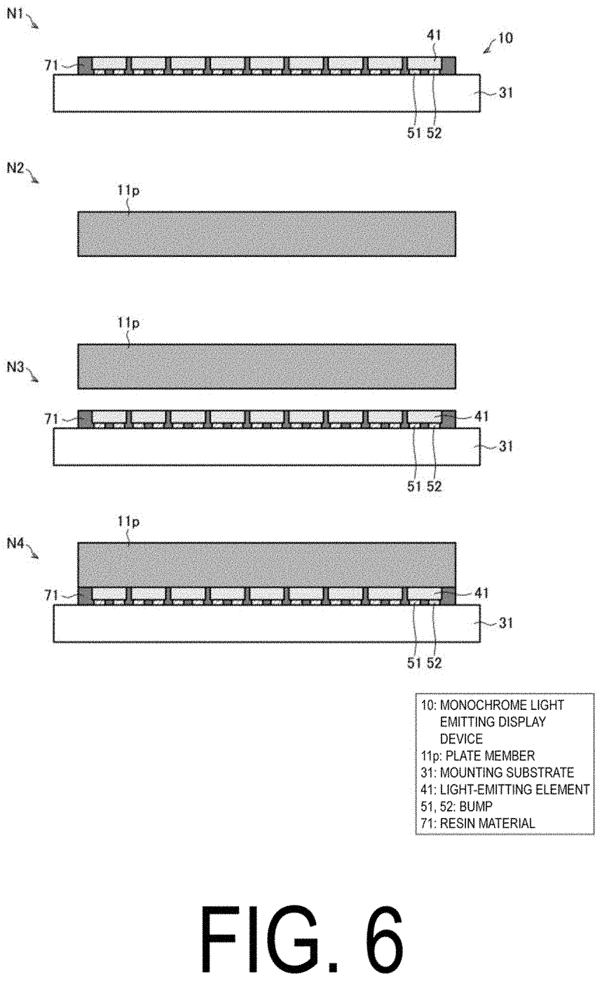

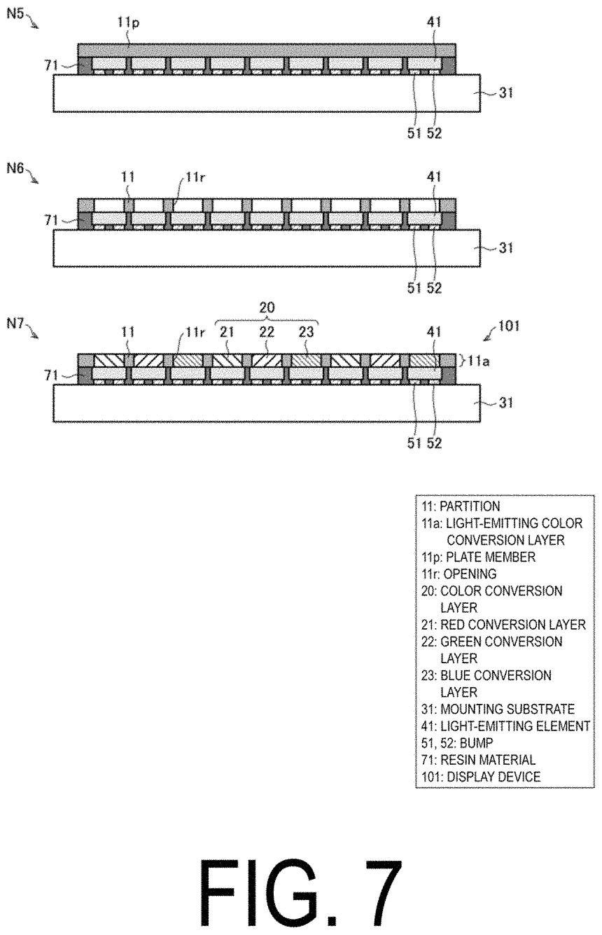

A method for manufacturing the display device 101 will be described with reference to steps N1 to N7 of FIGS. 6 and 7. FIGS. 6 and 7 are schematic cross-sectional views illustrating another example of the manufacturing process of the display device 101.

In step M3 of FIG. 4, the plate member 11p is machined to provide the recessed portion 11q, and then the plate member 11p is affixed to the monochrome light emitting display device 10. In contrast, in the present manufacturing method, the opening 11r is formed directly after the plate member 11p is affixed.

Specifically, as illustrated in step N1 of FIG. 6, after the monochrome light emitting display device 10 is prepared, a plate member 11p having a thickness which is easily handled is affixed to the light-emitting elements 41 side of the monochrome light emitting display device 10, as illustrated in steps N2 to N4 of FIG. 6.

Next, as illustrated in step N5 of FIG. 7, the plate member 11p is thinned to a desired thickness (a thickness of 4 μm if the thickness of the color conversion layer 20 is 4 μm, and a thickness of 10 μm if the thickness of the color conversion layer 20 is 10 μm) by mechanical grinding, wet or dry etching, and the like. Thereafter, as illustrated in step N6 of FIG. 7, the region substantially matching the light-emitting elements 41 is removed by dry etching to form the opening 11r. The color conversion layer 20 is provided similarly to step M7 of FIG. 5, and then the display device 101 is completed. Thus, the opening 11r is formed after the plate member 11p is affixed to the monochrome light emitting display device 10, and thus, the position of the light-emitting elements 41 and the opening 11r is easily aligned. If the affixing accuracy and the processing accuracy using photolithography are compared, the processing accuracy using photolithography is better.

### First Modification

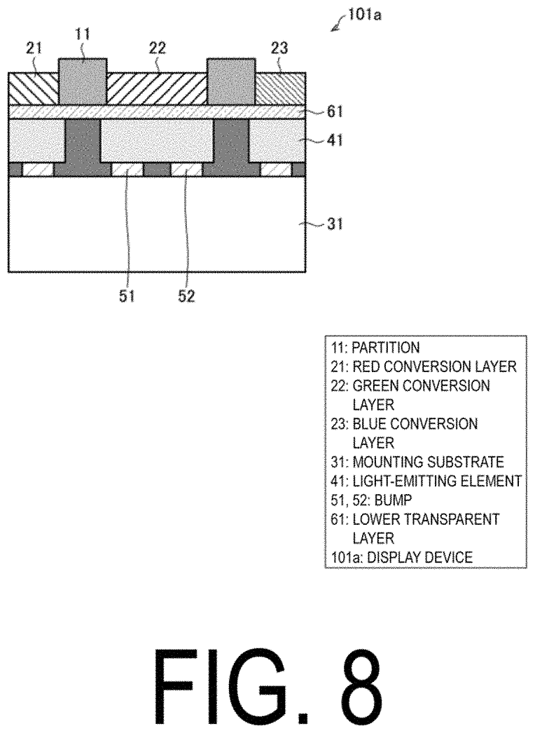

A display device 101a being a first modification of the display device 101 will be described with reference to FIG. 8. FIG. 8 is a detailed view of part A in L1 of FIG. 1, and is a schematic longitudinal cross-sectional view illustrating the first modification of the display device 101. As illustrated in FIG. 8, the display device 101a differs from the display device 101 in that a lower transparent layer 61 (transparent layer) is provided immediately below the color conversion layer 20 (on the light-emitting elements 41 side), and the other configuration is similar to each other.

The lower transparent layer 61 is layered immediately below the color conversion layer 20, that is, between the color conversion layer 20 and the light-emitting elements 41. The lower transparent layer 61 is desirably formed of a transparent inorganic material. In other words, the display device 101a includes the lower transparent layer 61 formed of an inorganic material between the light-emitting elements 41 and the color conversion layer 20.

The lower transparent layer 61 may be formed of a resin material, however, if the lower transparent layer 61 is formed of an inorganic material less permeable to moisture and oxygen, an effect for protecting the color conversion layer 20 (particularly, the quantum dot phosphor) from moisture and oxygen improves. In addition, whether the lower transparent layer 61 is formed of a transparent resin material or a transparent inorganic material, the color conversion layer 20 can be protected from heat generated by the light-emitting elements 41.

If the lower transparent layer 61 is formed of an inorganic material, for example, SiO2 or SiN can be employed to form the lower transparent layer 61 by an existing film forming method such as chemical vapor deposition (CVD). If the lower transparent layer 61 is formed of a resin material and a liquid resin is cured, the liquid resin may be applied or a spin coating method or the like can be employed. If the lower transparent layer 61 is a sheet-like resin, the lower transparent layer 61 can be formed by a method for affixing the sheet-like resin. In the case of an inorganic material, the lower transparent layer 61 may be formed also by affixing a plate member. If a light-emitting element 41 formed of a GaN-based material is employed in the display device 101a, it is even more preferable to employ a sapphire substrate being a growth substrate of a GaN layer.

The thickness of the lower transparent layer 61 is preferably smaller than the height of the partition 11. This is because if the thickness of the lower transparent layer 61 is more than the height of the partition 11, an amount of light leaking in the horizontal direction through the lower transparent layer 61 is more than an amount of light leaking as a result of the partition 11 being a transparent material, which results in crosstalk. The lower transparent layer 61 is capable of protecting the color conversion layer 20 from heat, moisture, and oxygen even if provided separately for each section of each of the color conversion layers 20. However, if the lower transparent layer 61 is provided integrally to cover the entire layer in which the color conversion layer 20 is provided, the color conversion layer 20 can be more reliably protected from moisture and oxygen.

Furthermore, a transparent conductive film may be employed for the lower transparent layer 61. It is possible to employ a transparent inorganic material such as indium tin oxide (ITO) for the transparent conductive film. The lower transparent layer 61 may be configured to cover the light-emitting elements 41 and the partition 11 after the partition 11 is provided. If a transparent conductive film serving as the lower transparent layer 61 is extended up to an electrode provided on a peripheral edge of the mounting substrate 31, and the transparent conductive film and the mounting substrate 31 are electrically connected, the transparent conductive film can serve as a conductor 52-2 described later. In other words, it is possible to electrically connect the partition 11 and the mounting substrate 31 by the transparent conductive film. As a result, as described in the second embodiment, it is possible to reduce the number of bumps that directly electrically connect the mounting substrate 31 and each of the light-emitting elements 41. Here, the electrode provided on the peripheral edge of the mounting substrate 31 indicates an electrical connection (not illustrated) between the conductor 52-2 described later and the mounting substrate 31 side.

Thus, in a configuration in which the lower transparent layer 61 covers the light-emitting elements 41 and the partition 11, even though the lower transparent layer 61 exists between the light-emitting elements 41 and the color conversion layer 20, an effect of heat from the light-emitting elements 41 on the color conversion layer 20 can be also reduced. Furthermore, in a configuration in which the light-emitting elements 41, and the side surface 11h and upper face 11m of the partition 11 are covered by a transparent conductive film, it is possible to more reliably protect the color conversion layer 20 from moisture and oxygen that easily penetrate from the resin material 71 and an interface between the resin material 71 and other constituent materials, an adhesive material if a resin material is used as an adhesive to provide the partition 11, and an interface between the adhesive material and other materials. The transparent inorganic material has a higher protective effect on the color conversion layer 20 from moisture and oxygen as compared with the transparent resin material, and if a transparent conductive film is employed for the transparent inorganic material, it is possible to electrically connect the partition 11 and the mounting substrate 31 because of the presence of a transparent electrode membrane conductor on at least one surface of the partition 11, similarly to a case where a metallic film exists on at least one face (at least one surface from the upper face m, the lower face 11n, or the side surface 11h) of the partition 11. Similar effects can be obtained even if an insulating material or a semiconductor material other than a conductive material is employed for the material of the partition 11.

### Method For Manufacturing Display Device 101a

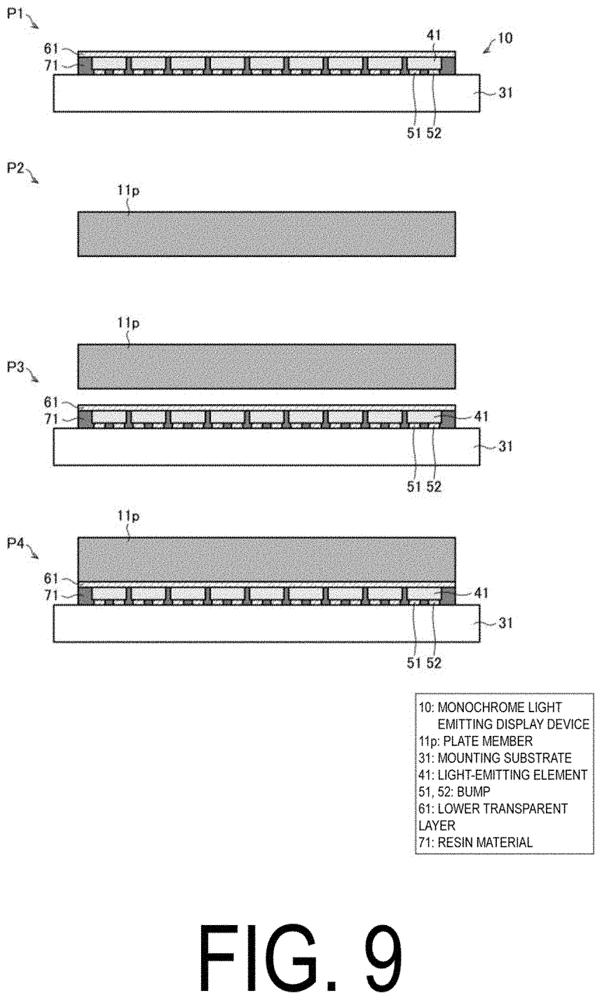

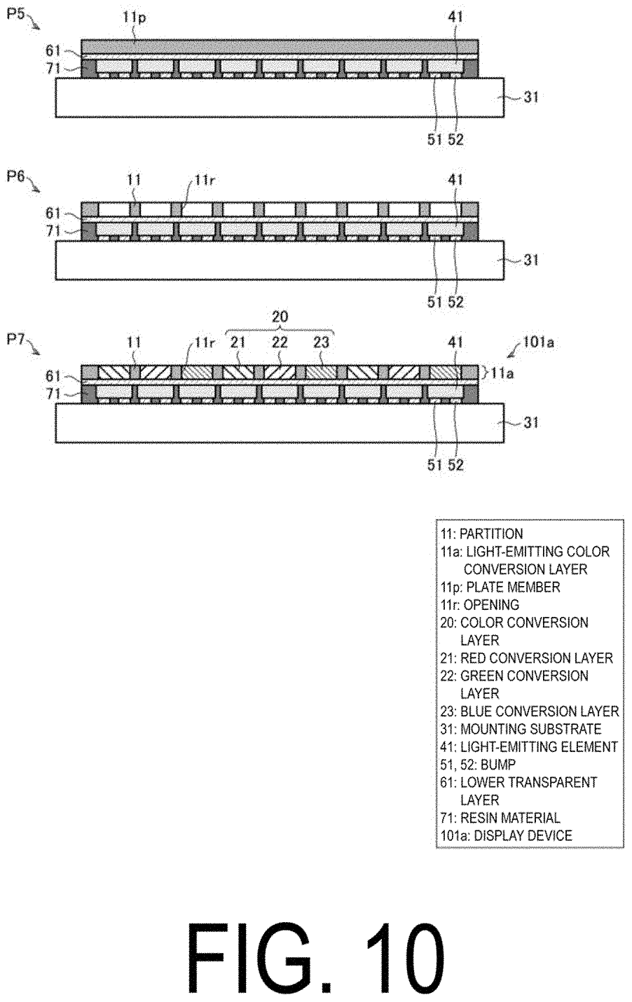

A method for manufacturing the display device 101a will be described with reference to steps P1 to P7 of FIGS. 9 and 10. FIGS. 9 and 10 are schematic cross-sectional views illustrating an example of a manufacturing process of the display device 101a. The method for manufacturing the display device 101a differs from the method for manufacturing the display device 101 only in a step of providing the lower transparent layer 61, and the other steps are similar to each other. Note that the process in steps P2 to P7 of FIGS. 9 and 10 is similar to that in steps N2 to N7 of FIGS. 6 and 7. In the present manufacturing method, a case in which the light-emitting elements 41 are formed of a GaN-based material and a sapphire substrate is employed for the growth substrate will be described.

In the method for manufacturing the display device 101a, in step P1 of FIG. 9, the lower transparent layer 61 is provided on the monochrome light emitting display device 10. If the GaN layer is grown on a sapphire substrate, for example, it is possible to easily obtain the lower transparent layer 61 by thinning and remaining the sapphire substrate on the surface of the monochrome light emitting display device 10 without completely removing the sapphire substrate. Specifically, in a step of preparing the monochrome light emitting display device 10, a GaN-based light-emitting element is formed on the sapphire substrate, and the GaN-based light-emitting element is divided by dry etching or the like on the sapphire substrate to include one or more light-emitting elements 41. The light-emitting element 41 on the sapphire substrate is then electrically connected to an LSI substrate being the mounting substrate 31 via the bumps 51 and 52.

In the step of preparing the monochrome light emitting display device 10 in the method for manufacturing the display device 101, the monochrome light emitting display device 10 in which the sapphire substrate is removed by a laser lift-off method is prepared. In contrast, in the step of preparing the monochrome light emitting display device 10 in the method for manufacturing the display device 101a, the monochrome light emitting display device 10 is prepared in which the sapphire substrate is not completely removed but thinned by mechanical grinding or the like. It is more preferable that the thickness of the sapphire substrate in this case is smaller in view of crosstalk. For example, the thickness of the sapphire substrate is made smaller than the height of the partition 11.

In step P2 and subsequent steps of FIG. 9, similarly to steps N2 to N7 of FIGS. 6 and 7, after the plate member 11p being a base material of the partition 11 is affixed on the monochrome light emitting display device 10, the opening 11r is provided. Similarly to steps M2 to M7 of FIGS. 4 and 5, after the recessed portion 11q is provided in the plate member 11p, the plate member 11p may be affixed to the monochrome light emitting display device 10. As described in the former, it is preferable to process the opening 11r after affixing the plate member 11p, making it easier to align the light-emitting elements 41 and the opening 11r.

The method for forming the lower transparent layer 61 is not limited to the above method. The method for forming the lower transparent layer 61 may employ a method for forming the lower transparent layer 61 by spin-coating a transparent resin on the monochrome light emitting display device 10 or on the surface of the plate member 11p (on the side with smooth surface roughness in a case of a silicon wafer). Furthermore, various methods for forming the lower transparent layer 61 can be employed, such as a method in which a transparent resin or a plate member formed of a transparent inorganic material is affixed on the monochrome light emitting display device 10 or on the surface of the plate member 11p.

### Second Modification

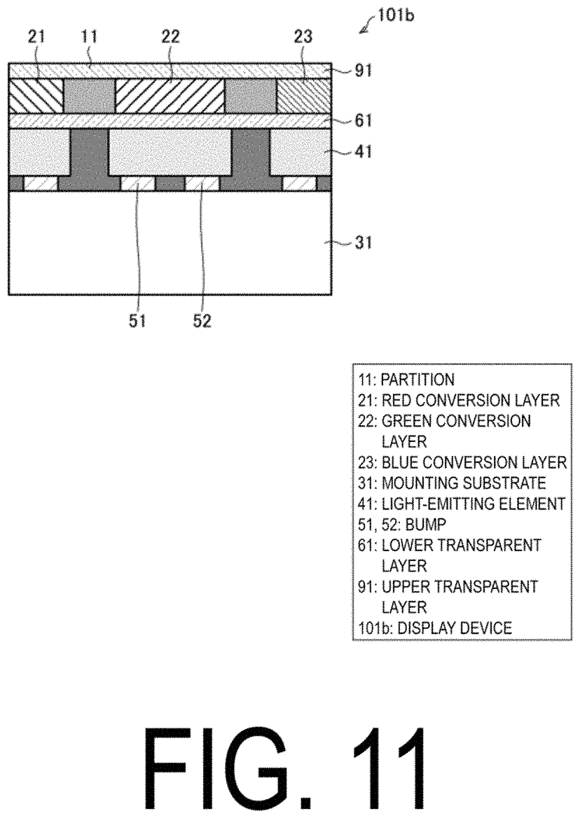

A display device 101b being a second modification of the display device 101 will be described with reference to FIG. 11. FIG. 11 is a detailed view of part A in L1 of FIG. 1, and is a schematic longitudinal cross-sectional view illustrating a second modification of the display device 101. As illustrated in FIG. 11, the display device 101b differs from the display device 101a in that an upper transparent layer 91 is provided above the color conversion layer 20 (on the side opposite to the light-emitting elements 41), and the other configuration is similar to each other.

The upper transparent layer 91 is layered above the color conversion layer 20, that is, on the light-emitting color conversion layer 11a. The upper transparent layer 91 is desirably formed of a transparent inorganic material. The upper transparent layer 91 may be formed of a resin material, but if the upper transparent layer 91 is formed of a transparent inorganic material, the color conversion layer 20 is further protected from moisture and oxygen. If a transparent resin material is employed for the upper transparent layer 91, the upper transparent layer 91 can be formed by applying or affixing the transparent resin material. If a transparent inorganic material is employed for the upper transparent layer 91, the upper transparent layer 91 can be formed by an existing film forming method such as CVD or by affixing the transparent inorganic material.

The upper transparent layer 91 is capable of protecting the color conversion layer 20 from moisture and oxygen even if provided separately for each section of each of the color conversion layers 20. However, if the upper transparent layer 91 is provided integrally to cover the entire display device 101b, the color conversion layer 20 can be more reliably protected from moisture and oxygen.

### Method For Manufacturing Display Device 101b

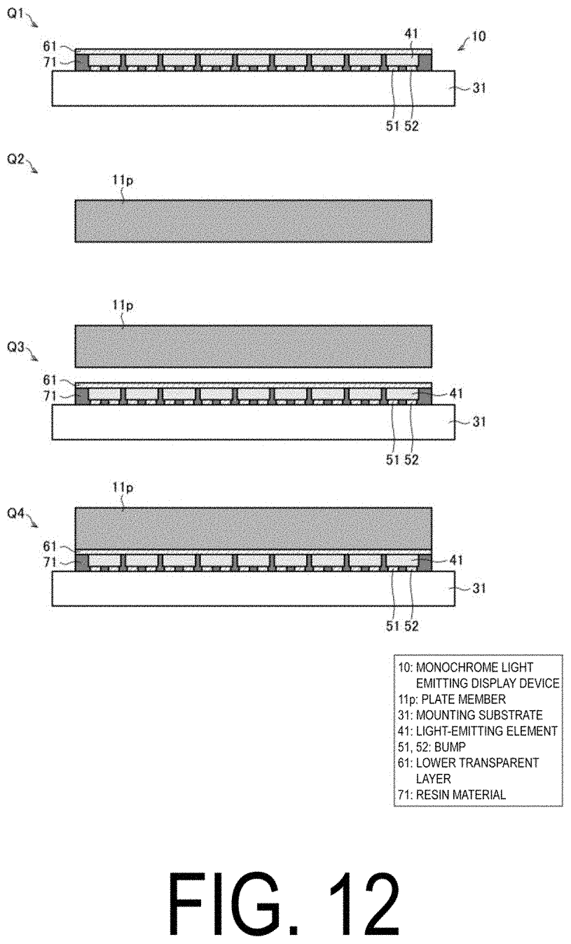

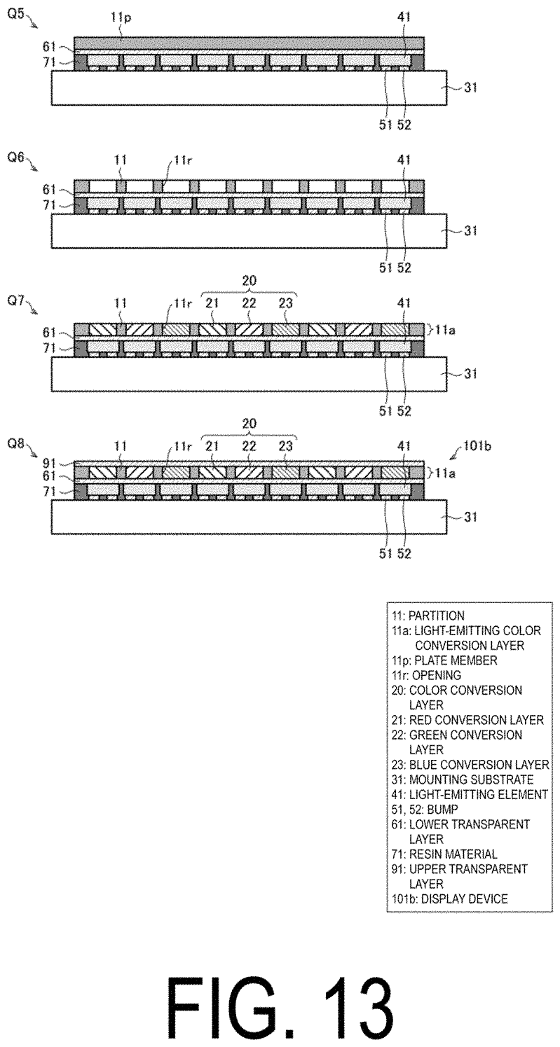

A method for manufacturing the display device 101b will be described with reference to steps Q1 to Q8 of FIGS. 12 and 13. FIGS. 12 and 13 are schematic cross-sectional views illustrating an example of a manufacturing process of the display device 101b. The method for manufacturing the display device 101b differs from the method for manufacturing the display device 101a in a step of providing the upper transparent layer 91, and the other steps are similar to each other. That is, the process in steps Q1 to Q7 of FIGS. 12 and 13 is similar to that in steps P1 to P7 in FIGS. 9 and 10.

In step Q8 of FIG. 13, the upper transparent layer 91 is provided on the color conversion layer 20. The upper transparent layer 91 can be provided by affixing a plate member formed of glass or the like being a transparent inorganic material, or a resin film being a transparent organic material to the light-emitting color conversion layer 11a. In this case, the plate member or the resin film is bonded to the light-emitting color conversion layer 11a via a photo-curable resin, a thermosetting resin, or a bonding material that combines the properties of both the photo-curable resin and the thermosetting resin provided on at least the upper face of the partition 11. A photo-curable resin is more effective for reducing an effect of heat on the color conversion layer 20 than a thermosetting resin.

As long as at least a portion of the upper face of the partition 11 and the upper transparent layer 91 are bonded in affixing the upper transparent layer 91, the color conversion layer 20 is less likely to be affected by moisture and oxygen from the outside. If the upper transparent layer 91 is bonded on the entire surface of the light-emitting color conversion layer 11a including the red conversion layer 21, the green conversion layer 22, and the blue conversion layer 23, it is possible to simplify the process. An adhesive material may be patterned on the upper transparent layer 91 or on the partition 11 by photolithography to substantially match the partition 11, and thereafter, the upper transparent layer 91 and the partition 11 may be bonded by heat or the like. Thus, the number of layers blocking light emitted from the light-emitting elements 41 can be reduced to improve the extraction efficiency of light emitted from the light-emitting elements 41 and subjected to color conversion.

Further, if the upper transparent layer 91 is bonded under a state of reduced air pressure or under a state in which inert gas is confined, it is possible to reduce an effect of moisture and oxygen present in the atmosphere on the color conversion layer 20 surrounded by the partition 11, the lower transparent layer 61, and the upper transparent layer 91.

In addition, the following (1) and (2) are considered for a method for providing the upper transparent layer 91. (1) The upper transparent layer 91 is formed by applying a liquid transparent resin on the partition 11 and each of the color conversion layers 20, and then covering the partition 11 and each of the color conversion layers 20 by spin coating. A photo-curable resin, a thermosetting resin, or a material that combines the properties of both the photo-curable resin and the thermosetting resin is employed for the liquid transparent resin. A photo-curable resin is more effective in reducing the effect of heat on each of the color conversion layers 20 than a thermosetting resin. (2) The upper transparent layer 91 is formed by providing a transparent inorganic material on each of the color conversion layers 20 by an existing film forming method such as a CVD method. The upper transparent layer 91 is effective in protecting the color conversion layer 20 from moisture and oxygen in the atmosphere without covering the entire upper face of the partition 11. If the upper transparent layer 91 is provided so that at least a part of the upper transparent layer 91 covers the upper face of the partition 11, the color conversion layer 20 can be protected from moisture and oxygen in the atmosphere more effectively.

If the upper transparent layer 91 is provided to cover the color conversion layer 20 and the partition 11 on the display device 101b, the upper transparent layer 91 can reliably protect the color conversion layer 20 from moisture and oxygen in the atmosphere.

### Third Modification

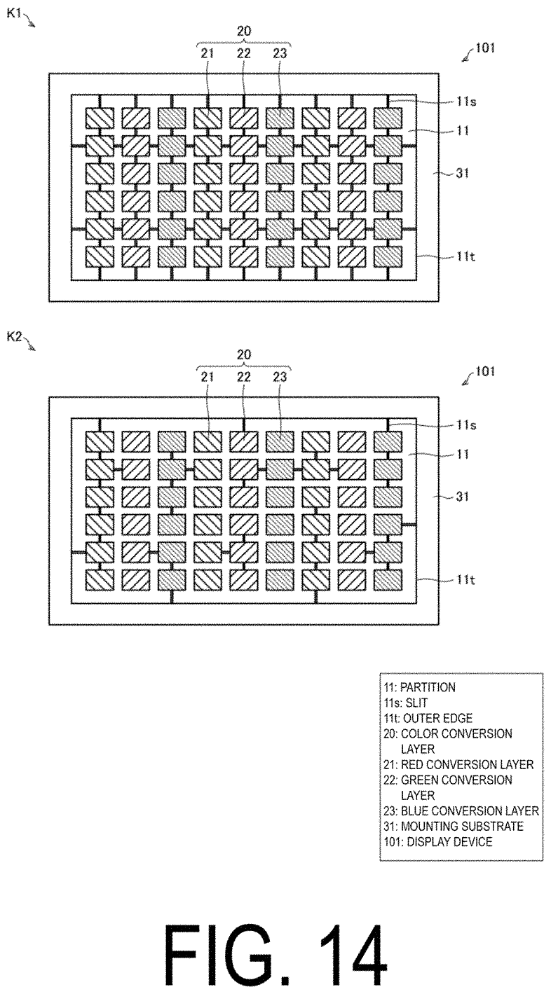

A third modification of the embodiment will be described with reference to FIG. 14. K1 of FIG. 14 is a plan view illustrating an example of an arrangement of slits 11s formed in the partition 11, and K2 of FIG. 14 is a plan view illustrating another example of the arrangement of the slits 11s formed in the partition 11.

In L2 of FIG. 1, each of the color conversion layers 20 is completely surrounded by the partition 11. However, the present embodiment is not limited to the above, and as illustrated in K1 of FIGS. 14 and K2 of FIG. 14, the partition 11 may include the slits 11s. The slits 11s connect adjacent color conversion layers 20, or connect the color conversion layer 20 and an outer edge 11t of the partition 11.

As the area of the partition 11 is wider, the partition 11 is more easily affected due to a difference in the coefficient of linear expansion between the partition 11 and a material around the partition 11 in the entire display device 101. In such a case as well, the thermal expansion difference can be absorbed by the slits 11s, and thus, the partition 11 is less likely to be deflected. Therefore, even if a material contacting with the partition 11 has a coefficient of linear expansion different from that of the partition 11, the effect of the difference can be reduced by the slits 11s.

In each of the color conversion layers 20, if a phosphor, a quantum dot phosphor, a pigment, or the like is contained in a resin having a predetermined viscosity, the width of each of the slits 11s is preferably a width at which the resin does not leak out. For example, the width of the slit 11s may be 1 μm or less.

There is a concern that light may slightly escape through the slits 11s, however, for example, it is possible to prevent different emitted color light from being mixed by providing the slits 11s between the red conversion layers 21, between the green conversion layers 22, or between the blue conversion layers 23, which emit same color light. As a result, it is possible to reduce a deterioration in visual display quality.

In K1 of FIG. 14, the slits 11s are formed to surround a fixed number of subpixels. In other words, the slits 11s are formed to divide the partition 11 into predetermined regions. In contrast, in K2 of FIG. 14, the slits 11s are provided in the partition 11 to always connect the partition 11 somewhere. In other words, the slits 11s are provided in the partition 11 so that the partition 11 is not separated in a plane. As illustrated in K2 of FIG. 14, a configuration in which the entire partition 11 is connected in the display device 101 is effective in setting the entire partition 11 to the same potential. Moreover, an effect for releasing heat through the partition 11 to the outer edge 11t side of the partition 11 is also improved.

### Comparison With Known Crosstalk Measures in Large Screen Liquid Crystal Display Device Such as TV

In known methods for displaying a color image in a display device, a method is commonly known in which light from a monochrome light emitting display device is passed through a color conversion layer to extract three primary light colors of red, blue, and green from the monochrome light to display a color image. Examples of the color conversion layer include a phosphor, a quantum dot phosphor, and a color filter. The phosphor or the quantum dot phosphor converts a wavelength of incident light into light having a different wavelength. The color filter emits, for example, only red, blue, or green light if light (white light) in which red, blue, and green being, for example, three primary light colors are mixed up enters. Thus, the color conversion layer refers to a layer that converts a wavelength and distribution of light entering the color conversion layer to convert a color.

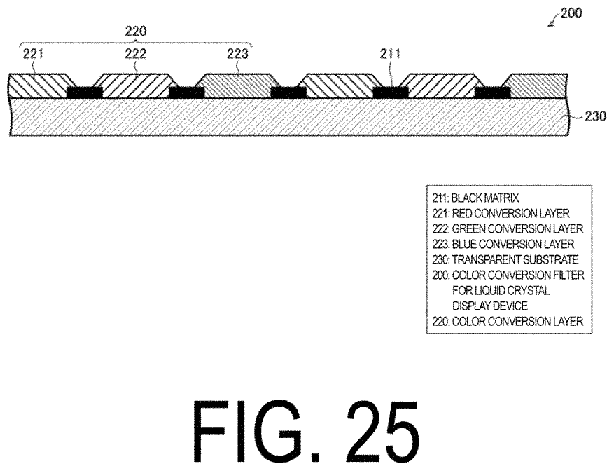

To improve crosstalk where light of each pixel or subpixel mixes with light of adjacent pixels or subpixels, a black matrix is typically provided in a color conversion filter 200 or the like for a large screen liquid crystal display device such as a TV. FIG. 25 illustrates a cross-sectional structure of a common color conversion layer 220 employed in the color conversion filter 200 or the like for a liquid crystal display device.

In the color conversion filter 200 for a liquid crystal display device, an LED package in which light from a blue LED is converted into white light by a phosphor to emit light is employed for a backlight. Therefore, the color conversion layer 220 generally employs only a color filter that extracts three primary colors from white color.

The black matrix is formed of chromium or a black resin and is formed in a matrix shape in a plane, and in a thin film shape in a cross-sectional structure. The color filter of the color conversion layer 220 is required to be formed with a thickness of 2 μm or greater, and thus, the color filter is formed by photolithography to overlap a black matrix having a thickness of 1 μm or less.

It is desirable that a region in which the black matrix is formed ideally falls in a region between subpixels, that is, in a space region in which subpixels are not present, so that light from each light-emitting portion (subpixel) of the display device is not obstructed. There is some margin between color filters in the color conversion filter 200 for a large screen liquid crystal display device such as a TV, and thus, there is a sufficient dimensional margin even in a structure in which the color filter overlaps the black matrix.

However, in mobile display devices requiring subpixels in microns, particularly, mobile display devices having a size of 50 mm or less even in the longer direction, a space region is extremely small. Thus, there is no dimensional margin for the color filter to overlap the black matrix. Accordingly, crosstalk measures different from those for a typical black matrix employed in the color conversion filter 200 for a liquid crystal display device are required.

According to an aspect of the present disclosure, it is possible to reduce crosstalk of light without forming a black matrix by the partition 11. As a result, it is possible to reduce crosstalk of light even in a mobile display device.

### Comparison With Technique of PTL 1

As described above, in the color conversion filter according to PTL 1, a first layer being a color conversion layer for a color filter, and a second layer being a color conversion layer including a color conversion pigment are formed on a transparent substrate. The color conversion layer as the first layer is partitioned by a black matrix. The color conversion layer as the second layer is partitioned by a bank layer formed of a transparent resin or a transparent inorganic material. The color conversion layer as the second layer is required to have a thickness of 2 μm, and thus, is formed with a bank layer with a thickness of 3 μm, instead of a black matrix. The color conversion filter according to PTL 1 requires a thickness of 10 μm or greater if only the color conversion layer containing the color conversion pigment is provided, and thus, the thickness of the color conversion layer containing the color conversion pigment is reduced by combining with a color filter.

In the color conversion layer as the first layer, a color filter is formed in the region surrounded by the black matrix to overlap the black matrix, and thus, in the color conversion layer as the first layer, a step equivalent to the height of the black matrix occurs. Therefore, in the color conversion filter, a flattened layer formed of a transparent resin for flattening an upper layer of the color conversion layer as the first layer is provided. On the flattened layer, the bank layer in the second layer is formed of the same transparent resin as the flattened layer, or a transparent inorganic oxide such as SiOx, SiNx, SiNxOy, AlOx, TiOx, TaOx, and ZnOx, or a transparent inorganic nitride. The bank layer in the color conversion layer as the second layer needs to employ a transparent resin that is easily subjected to photolithography to increase the height of the bank layer.

Thus, the color conversion filter described in PTL 1 employs a transparent resin or a transparent inorganic material for the bank layer, and thus, in the color conversion layer having a color conversion pigment, a problem of crosstalk occurs because of light leakage in the horizontal direction from adjacent subpixels.

In contrast, in the display device 101 according to the first aspect of the present disclosure, the partition 11 that separates a region in which each color conversion layer is provided is formed of an inorganic material having a light-shielding property. As a result, it is possible to prevent light leakage in the horizontal direction from adjacent subpixels and thus prevent crosstalk from occurring.

Furthermore, in the conversion filter, a black matrix for the color filter, and a bank layer for the color conversion layer including a color conversion pigment are respectively formed. In the color conversion filter, it is necessary to add a flattened layer. As a result, the manufacturing process is very complex.

In addition, the resin included in the black matrix contains carbon black or the like, and thus, it is difficult to form a thick film of 2 μm or greater by photolithography. Furthermore, even if the black matrix is formed of chromium, it is difficult to form a 1 μm or thicker film because the film is formed by sputtering.

In contrast, the display device 101 according to the first aspect of the present disclosure does not employ a black matrix, and thus, it is possible to avoid problems such as those described above.

According to the first aspect of the present disclosure, the light-emitting elements 41 rather than a light-emitting element sealed package in which the light-emitting elements 41 are individually sealed are arranged directly on the mounting substrate 31. As a result, even a small-size display device (mobile display device) that cannot employ a structure in which light-emitting element sealed packages in which the light-emitting elements 41 are sealed are arranged on the mounting substrate 31 can employ the structure according to the first aspect of the present disclosure.

### Second Embodiment

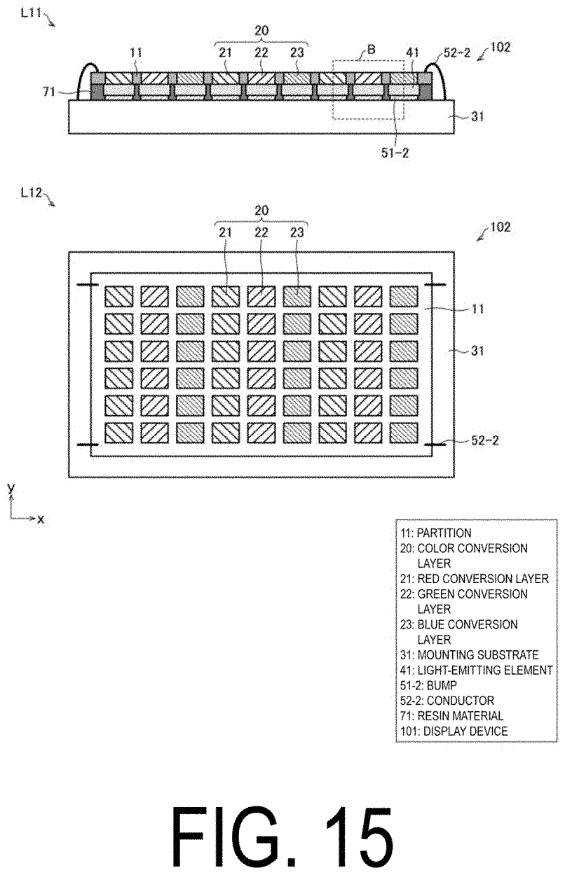

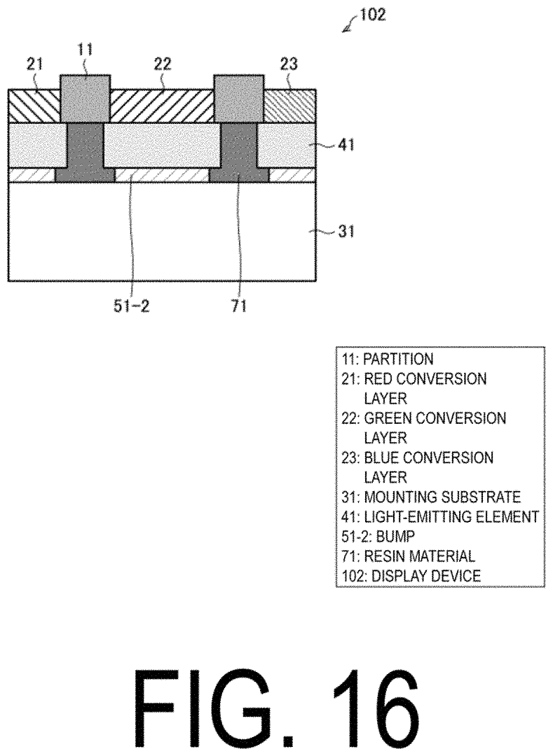

A display device 102 according to a second embodiment of the present disclosure will be described with reference to FIGS. 15 and 16. L11 of FIG. 15 is a schematic longitudinal cross-sectional view of the display device 102 according to the second embodiment of the present disclosure, and L12 of FIG. 15 is a plan view of the display device 102. FIG. 16 is a detailed view of part B in L11 of FIG. 15. Note that, for convenience of explanation, components having the same functions as those described in the above-described embodiment will be denoted by the same reference signs, and descriptions of those components will be omitted.

### Configuration of Display Device 102

As illustrated in FIGS. 15 and 16, the display device 102 differs from the display device 101 in a method for electrically connecting the mounting substrate 31 and the light-emitting elements 41, and the other configuration is similar to each other. Specifically, the display device 102 includes a single bump, that is, a bump 51-2 that directly electrically connects an LSI substrate being the mounting substrate 31, and the anode electrode of the light-emitting elements 41. The cathode electrode of the light-emitting elements 41 is electrically connected to the mounting substrate 31 via an upper face of the partition 11 (a surface opposite to the mounting substrate 31) and a conductor 52-2. In other words, the light-emitting elements 41 are provided above the mounting substrate 31 while being electrically connected to the mounting substrate 31 and the partition 11, and the partition 11 is electrically connected to the mounting substrate 31. In other words, one electrode of the light-emitting elements 41 is connected to the mounting substrate 31 via the bump 51-2, and the other electrode of the light-emitting elements 41 is connected to the mounting substrate 31 via the partition 11 and the conductor 52-2.

The mounting substrate 31 and the light-emitting elements 41 may be electrically connected by connecting the cathode electrode of the light-emitting elements 41 and the mounting substrate 31 via the bump 51-2, and the anode electrode of the light-emitting elements 41 and the mounting substrate 31 may be connected via the partition 11 and the conductor 52-2. If the anode electrode of the light-emitting elements 41 and the mounting substrate 31 are connected via the bump 51-2, and the cathode electrode of the light-emitting elements 41 and the mounting substrate 31 are connected via the partition 11 and the conductor 52-2, it is easier in the manufacturing process.

In the display device 101, the two bumps 51 and 52 are required for the electrical connection between the mounting substrate 31 and the light-emitting elements 41. In contrast, in the display device 102, only one bump is required for the connection.

In addition, the partition 11 is formed of a metallic or semi-metallic material, and thus, each of the light-emitting elements 41 and the partition 11 are easily electrically connected by providing one electrode (either the cathode electrode or the anode electrode) on the upper face side of the light-emitting elements 41. The partition 11 can serve as a conductor for a common electrode of each of the light-emitting elements 41.

The partition 11 may be formed of a semi-metallic material, however the partition 11 formed of a metallic material is suitable because the electrical conductivity improves. If aluminum is employed for a material of the partition 11, the side surface of the partition 11 is an extremely favorable metallic lustrous surface, making the partition 11 suitable as a conductor for the light-emitting elements 41.

In the display device 102, the number of bumps to which the light-emitting elements 41 and the mounting substrate 31 are directly connected may be one that is a bump 51-2 for each light-emitting element 41. As a result, the size of the bump 51-2 can be increased. The size of the bump 51-2 refers to the area of a x-y plane, the dimension in the x-direction, or the dimension in the y-direction of the bump 51-2. This facilitates direct electrical connection between the mounting substrate 31 and the light-emitting elements 41.

As described earlier, in order to achieve a mobile display device having a size of 50 mm square or smaller, subpixels are of a size so that a pitch between the subpixels is approximately 8.7 μm or less, and thus, the size of the light-emitting elements 41 is 8.7 μm or smaller. For example, two bumps, that is, the bumps 51 and 52 are required in the display device 101 if the size of the light-emitting elements 41 is 8 μm×8 μm, and thus, the size of each of the bumps is required to be smaller than approximately half of the size of 8 μm×4 μm. Furthermore, it is necessary to further reduce the size of the cathode electrode and the anode electrode in consideration of safety to prevent electrical shorts. Thus, it is clear that if the number of bumps to which the light-emitting elements 41 and the mounting substrate 31 are directly connected is one rather than two, it is easier to mount the light-emitting elements 41 on the mounting substrate 31.

As described earlier, a mobile display device may include subpixels whose pitch is approximately 2.6 μm or less. Even in such a case, it is preferable that the number of bumps to which the light-emitting elements 41 and the mounting substrate 31 are directly connected is one. The size of the bump affects the alignment accuracy between the mounting substrate 31 and the electrodes of the light-emitting elements 41.

In addition, if the number of bumps to which the light-emitting elements 41 and the mounting substrate 31 are directly connected is one, it is more likely to suppress electrical shorts with adjacent bumps. There is no need to ensure a space between bumps provided for the same light-emitting element 41 (between the bumps 51 and the bumps 52 in the display device 101), and thus, a bonding area of the bump can be increased to bond the bump with high reliability.

A bonding gold wire, aluminum wire, or the like, or an aluminum ribbon material, a copper ribbon material, or the like may be employed for the conductor 52-2. The conductor 52-2 may also be provided by an existing film forming method such as plating, vapor deposition, or sputtering of metal. The partition 11 and the electrodes of the mounting substrate 31 may be electrically connected by a conductive paste containing conductive particles. Additionally, the partition 11 and the electrodes of the mounting substrate 31 may be electrically connected by a transparent wiring material such as ITO.

### Example of Manufacturing Method

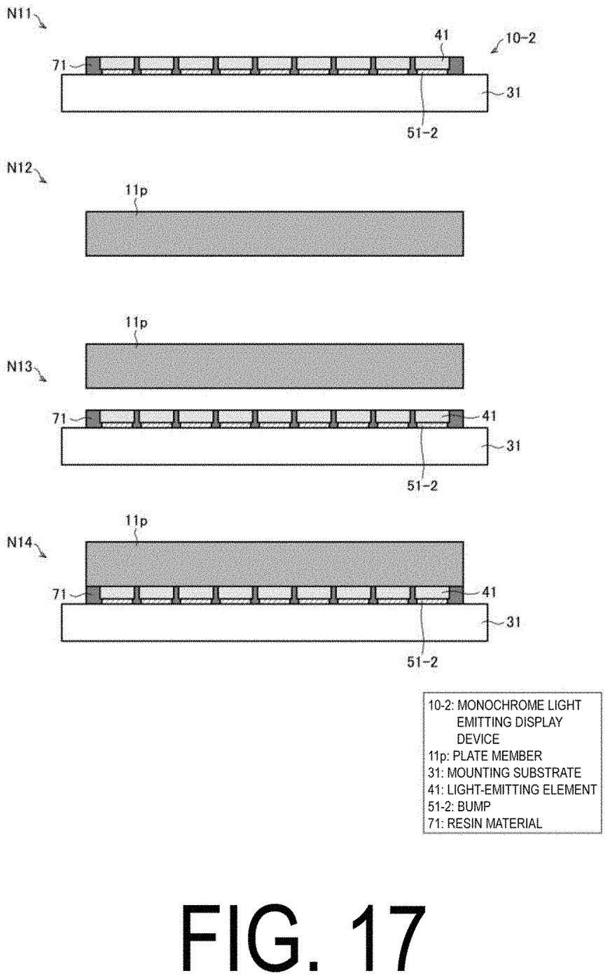

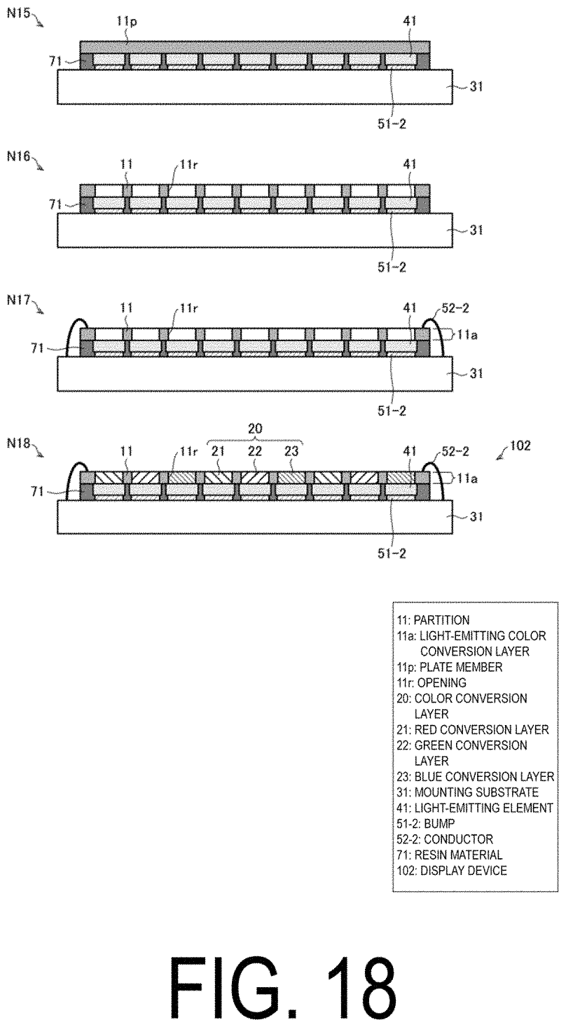

An example of a method for manufacturing the display device 102 will be described with reference to steps N11 to N18 of FIGS. 17 and 18. FIGS. 17 and 18 are schematic cross-sectional views illustrating an example of a manufacturing process of the display device 102. The method for manufacturing the display device 102 differs from the method for manufacturing the display device 101 in a step of providing the conductor 52-2, and a structure of the light-emitting elements 41 themselves, and the other steps are similar to each other. Thus, the process in steps N11 to N16 of FIGS. 17 and 18 is similar to that in steps N1 to N6 in FIGS. 6 and 7, except for the bumps.

Specifically, in the method for manufacturing the display device 102, a mobile monochrome light emitting display device 10-2 is prepared in step N11 of FIG. 17. The monochrome light emitting display device 10-2 differs from the monochrome light emitting display device 10 in size and the number of bumps. The electrodes of the light-emitting elements 41 are provided at the top and bottom.

As described earlier, the display device 102 differs from the display device 101 in that either of the cathode electrode or the anode electrode of each of the light-emitting elements 41 is bundled together as a common electrode, and the conductor 52-2 is provided. In the display device 102, the conductor 52-2 is provided to causes the partition 11 to serve as a conductor for electrically connecting the common electrode and the mounting substrate 31.

The method for manufacturing the display device 102 includes a connection step (a step of providing the conductor 52-2) of electrically connecting a substrate (the mounting substrate 31) on which the light-emitting elements 41 are arranged and the partition 11, the substrate being electrically connected to the light-emitting elements 41. The step of providing the conductor 52-2 is performed after the partition providing step, in other words, after step M6 of FIG. 5 or step N6 of FIG. 7 in the manufacturing process of the display device 101, that is, after the partition providing step in step N16 of FIG. 18 in the manufacturing process of the display device 102. If the effect of heat on the color conversion layer 20 is small, the step of providing the conductor 52-2 may be performed after the color conversion layer providing step, in other words, after step M7 of FIG. 5 or step N7 of FIG. 7 in the manufacturing process of the display device 101, that is, after step N18 of FIG. 18 in the manufacturing process of the display device 102. To further reduce the effect of heat on the color conversion layer 20, the step of providing the conductor 52-2 is preferably performed after the partition providing step.

### First Modification

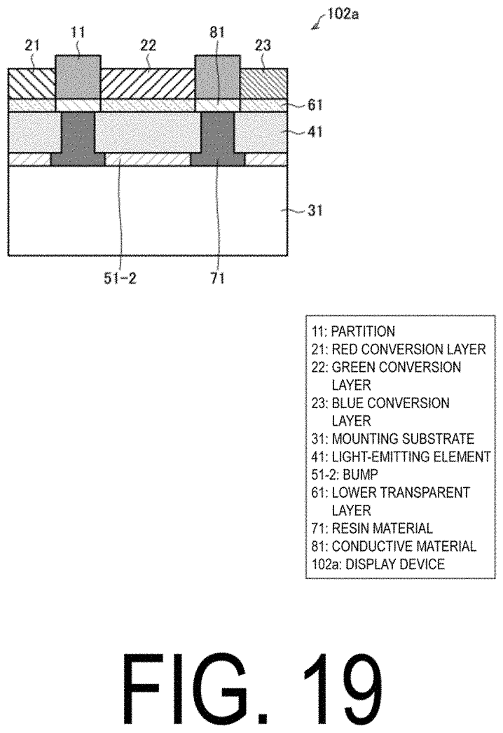

A display device 102a being a first modification of the display device 102 will be described with reference to FIG. 19. FIG. 19 is a detailed view of part B in L11 of FIG. 15, and is a schematic longitudinal cross-sectional view illustrating the first modification of the display device 102. As illustrated in FIG. 19, the display device 102a differs from the display device 102 in that the lower transparent layer 61 and the conductive material 81 are provided immediately below the color conversion layer 20, and the other configuration is similar to each other.

The display device 102a includes the lower transparent layer 61 formed of an inorganic material between the light-emitting elements 41 and the color conversion layer 20, and the light-emitting elements 41 and the partition 11 are electrically connected by the conductive material 81 provided to penetrate the lower transparent layer 61. The conductive material 81 is provided immediately below the partition 11 to at least partially overlap the light-emitting elements 41, and electrically connects the partition 11 and the light-emitting elements 41. As a result, even if the partition 11 is used as a conductor for the common electrode of the light-emitting elements 41, the color conversion layer 20 can be protected by the lower transparent layer 61.

The lower transparent layer 61 may be a transparent conductive film. In this case, the partition 11 may be fixed by the conductive material 81 on the lower transparent layer 61.

Furthermore, a transparent conductive film may be employed for the lower transparent layer 61. A transparent inorganic material such as ITO may be employed for the transparent conductive film. The lower transparent layer 61 may be configured to cover the light-emitting elements 41 and the partition 11 after the partition 11 is provided. If a transparent conductive film serving as the lower transparent layer 61 is extended up to an electrode provided on a peripheral edge of the mounting substrate 31, and the transparent conductive film and the mounting substrate 31 are electrically connected, the transparent conductive film can serve as a conductor 52-2. In other words, it is possible to electrically connect the partition 11 and the mounting substrate 31 by the transparent conductive film.

Thus, in a configuration in which the lower transparent layer 61 covers the light-emitting elements 41 and the partition 11, even though the lower transparent layer 61 exists between the light-emitting elements 41 and the color conversion layer 20, an effect of heat from the light-emitting elements 41 on the color conversion layer 20 can be also reduced. Furthermore, in a configuration in which the light-emitting elements 41, and the side surface 11h and upper face 11m of the partition 11 are covered by a transparent conductive film, it is possible to more reliably protect the color conversion layer 20 from moisture and oxygen that easily penetrate from the resin material 71 and an interface between the resin material 71 and other constituent materials, an adhesive material if a resin material is used as an adhesive to provide the partition 11, and an interface between the adhesive material and other materials. The transparent inorganic material has a higher protective effect on the color conversion layer 20 from moisture and oxygen as compared with the transparent resin material, and if a transparent conductive film is employed for the transparent inorganic material, it is possible to electrically connect the partition 11 and the mounting substrate 31 because of the presence of a transparent electrode membrane conductor on at least one surface of the partition 11, similarly to a case where a metallic film exists on at least one face (at least one surface from the upper face m, the lower face 11n, or the side surface 11h) of the partition 11. Similar effects can be obtained even if an insulating material or a semiconductor material other than a conductive material is employed for the material of the partition 11.

### Method For Manufacturing Display Device 102a

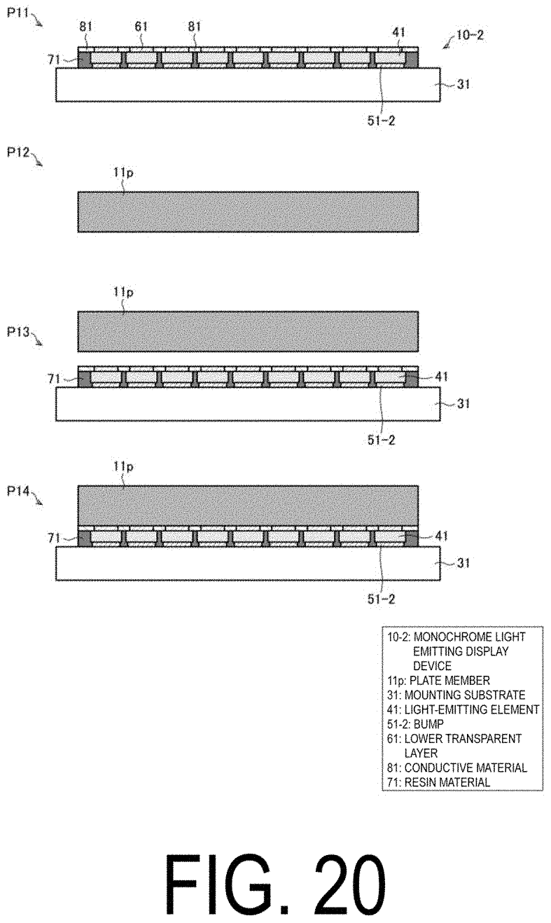

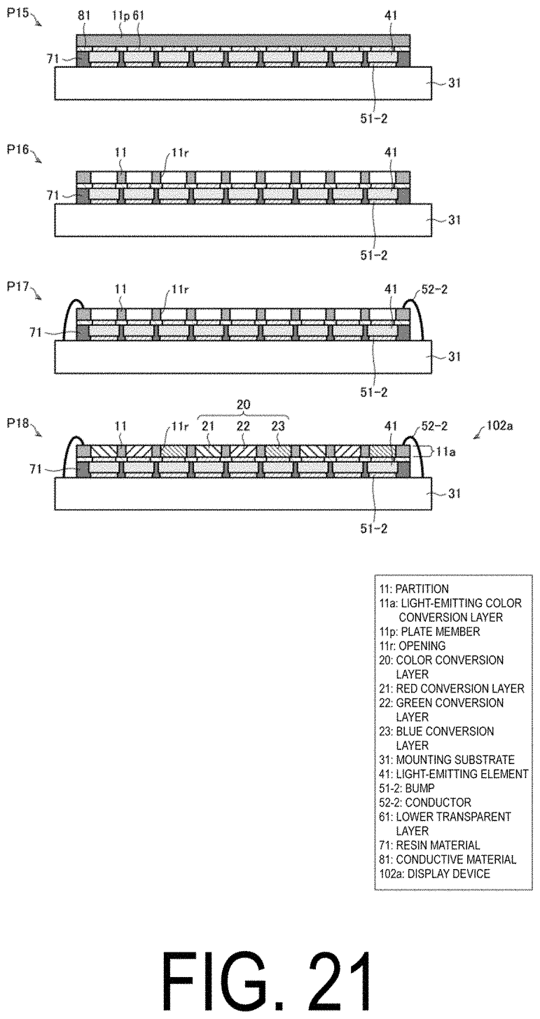

A method for manufacturing the display device 102a will be described with reference to steps P11 to P18 of FIGS. 20 and 21. FIGS. 20 and 21 are schematic cross-sectional views illustrating an example of a manufacturing process of the display device 102a. The method for manufacturing the display device 102a differs from the method for manufacturing the display device 102 only in a step of providing the lower transparent layer 61 and the conductive material 81, and the other steps are similar to each other. Note that the process in steps P12 to P18 in FIGS. 20 and 21 is the same as that in steps N12 to N18 of FIGS. 17 and 18.

In the method for manufacturing the display device 102a, in step P11 of FIG. 20, the lower transparent layer 61 and the conductive material 81 are provided on the mobile monochrome light emitting display device 10-2. It is possible to obtain the lower transparent layer 61 by a method similar to that in the first modification of the first embodiment. In addition, the conductive material 81 can be provided by removing the lower transparent layer 61 in a region between the light-emitting elements 41 and a region overlapping a portion of the light-emitting elements 41, and applying a material having conductivity to the regions where the lower transparent layer 61 is removed.

In addition, if a transparent conductive film is provided as the lower transparent layer 61, patterning for removing the lower transparent layer 61 can be omitted, and thus, a simpler manufacturing method can be achieved.

Further, in step P11, only the conductive material 81 may be provided on the light-emitting elements 41, in at least a peripheral edge portion of the light-emitting elements 41, and after step P16, a transparent conductive film may be provided as the lower transparent layer 61, on the light-emitting elements 41, and the side surface 11h and the upper face 11m of the partition 11. If a transparent conductive film is extended up to an electrode provided on a peripheral edge of the mounting substrate 31, and the transparent conductive film and the mounting substrate 31 are electrically connected, the transparent conductive film can serve as the conductor 52-2 provided in step P17. As a result, step P17 is simplified. Thus, if the transparent conductive film is employed, the conductive material 81 may preferably serve as an adhesive material, or may be an insulating material.

### Second Modification

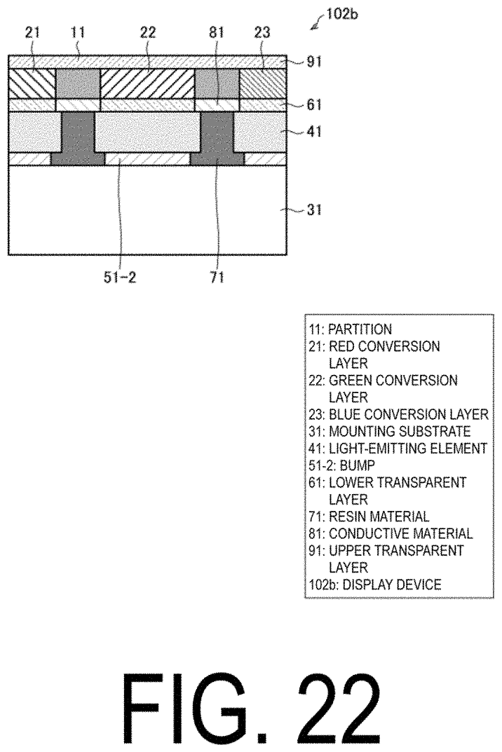

A display device 102b being a second modification of the display device 102 will be described with reference to FIG. 22. FIG. 22 is a detailed view of part B in L11 of FIG. 15, and is a schematic longitudinal cross-sectional view illustrating a second modification of the display device 102. As illustrated in FIG. 22, the display device 102b differs from the display device 102a in that an upper transparent layer 91 is provided above the color conversion layer 20, and the other configuration is similar to each other. The configuration of the upper transparent layer 91 is as described in the second modification of the first embodiment. The upper transparent layer 91 is preferably provided away from the conductor 52-2. However, if a transparent conductive film material is provided above each of the color conversion layers 20 as the upper transparent layer 91, the conductor 52-2 may also serve as the upper transparent layer 91, which is even better.

In the display devices 101, 101a, 101b, 102, 102a, and 102b, the partition 11 is provided above the light-emitting elements 41. The partition 11 may not be arranged at a position overlapping the light-emitting elements 41, or may be formed on the resin material 71. Moreover, the partition 11 may be provided on the side of the light-emitting elements 41, and may have a structure in which the partition 11 is higher than the upper face of the light-emitting element 41 from the side, by as much as the thickness of the color conversion layer 20. In other words, the partition 11 includes a plurality of the partitions 11, and a configuration may be employed in which the partition 11 is provided on the mounting substrate 31, the light-emitting elements 41 may be provided between the partitions 11, and the color conversion layer 20 is provided on the light-emitting elements 41 and between the light-emitting elements 41 and the partition 11. In this case, the partition 11 has a height equal to or greater than a height obtained by combining the height of the light-emitting elements 41 and the thickness of the color conversion layer 20 on the light-emitting elements 41.

### Method For Manufacturing Display Device 102b

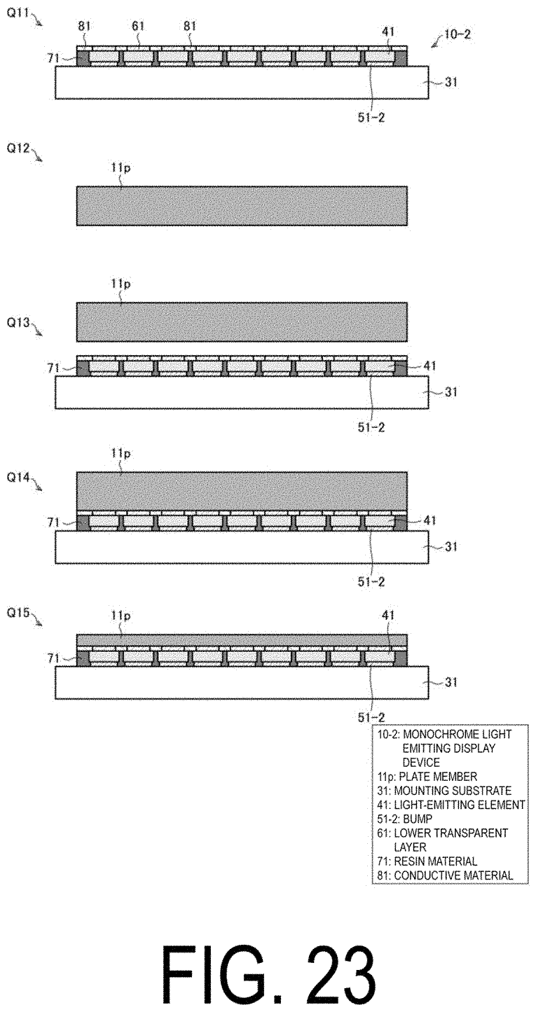

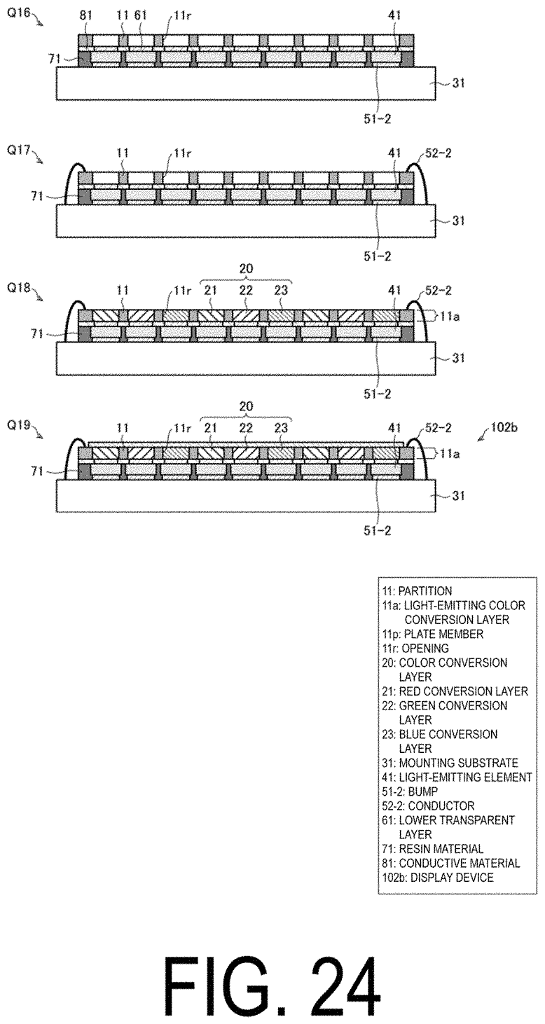

A method for manufacturing the display device 102b will be described with reference to steps Q11 to Q19 of FIGS. 23 and 24. FIGS. 23 and 24 are schematic cross-sectional views illustrating an example of a manufacturing process of the display device 102b. The method for manufacturing the display device 102b differs from the method for manufacturing the display device 102a in a step of providing the upper transparent layer 91, and the other steps are similar to each other. That is, the process in steps Q11 to Q18 of FIGS. 23 and 24 is the same as that in steps P11 to P18 of FIGS. 20 and 21. In addition, the method for manufacturing the upper transparent layer 91 in step Q19 of FIG. 24 is as described in the second modification of the first embodiment.

### Supplement

A display device (101, 101A) according to a first aspect of the present disclosure includes a plurality of light-emitting elements (41), color conversion layers (20) that convert a color of light emitted from the plurality of light-emitting elements, and a partition (11) that separates a region provided with each of the color conversion layers (20), the partition (11) being formed of an inorganic material having a light-shielding property.

According to the configuration, in the display device, the partition that separates the region provided with each of the color conversion layers is formed of an inorganic material having a light-shielding property, and thus, light emitted from adjacent color conversion layers is less likely to mix. As a result, it is possible to suppress occurrence of crosstalk of light.

In the display device (101, 101A) according to a second aspect of the present disclosure, in the first aspect, the partition (11) may be formed of a material having metallic luster.

According to the configuration, in the display device, the partition has metallic luster, and thus reflects light. As a result, an extraction efficiency of light from each of the color conversion layers improves.

In the display device (101A) according to a third aspect of the present disclosure, in the first aspect and the second aspect, the partition may be formed of a material having conductivity, the plurality of light-emitting elements (41) may be provided above a substrate (the mounting substrate 31), the plurality of light-emitting elements being electrically connected to the substrate and the partition (11), and the partition (11) may be electrically connected to the substrate.

According to the configuration, it is possible to use the partition as a conductor for a common electrode of the plurality of light-emitting elements. Thus, for example, only one point is required where the substrate and each of the plurality of light-emitting elements are directly electrically connected. As a result, it is easy to electrically connect the substrate and the plurality of light-emitting elements.

In the display device according to a fourth aspect of the present disclosure, in the first aspect and the second aspect, a conductive film may be formed on at least a part of a surface of the partition, the plurality of light-emitting elements may be provided above a substrate, the plurality of light-emitting elements being electrically connected to the substrate and the conductive film, and the conductive film may be electrically connected to the substrate.

According to the configuration, it is possible to use the conductive film as a conductor for a common electrode of the plurality of light-emitting elements. Thus, for example, only one point is required where the substrate and each of the plurality of light-emitting elements are directly electrically connected. As a result, it is easy to electrically connect the substrate and the plurality of light-emitting elements.

The display device (101) according to a fifth aspect of the present disclosure may include, in any one of the first to the fourth aspects, a transparent layer (the lower transparent layer 61) formed of an inorganic material between the plurality of light-emitting elements (41) and the color conversion layers (20).

According to the configuration, if a transparent layer is provided between the plurality of light-emitting elements and the color conversion layers, it is possible to protect the color conversion layers from heat generated by the plurality of light-emitting elements without obstructing incidence of light from the plurality of light-emitting elements to the color conversion layers. If the transparent layer is formed of an inorganic material, it is possible to suitably protect the color conversion layers from moisture and oxygen.

In the display device according to a sixth aspect of the present disclosure, in any one of the first to fifth aspects, slits (11s) may be formed in the partition (11), the slits (11s) connecting adjacent ones of the color conversion layers (20), or connecting the color conversion layers (20) and an outer edge (11t) of the partition.

According to the configuration, the slits that connect the adjacent color conversion layers, or connect the color conversion layers and the outer edge of the partition are formed in the partition. Therefore, if a difference of expansion occurs between the partition and the other constituent materials, the expansion can be absorbed by the slits. As a result, even if the coefficient of linear expansion is different between the partition and the other constituent materials, it is possible to reduce an effect of the difference.

A method for manufacturing a display device according to a seventh aspect of the present disclosure includes a partition providing step of providing, in a display device (101, 101A) emitting monochrome light and in which a plurality of light-emitting elements (41) are arranged, a space (the opening 11r) separated by a partition (11) formed of an inorganic material having a light-shielding property, to substantially match an arrangement of each of the plurality of light-emitting elements (41), and a color conversion layer providing step of providing, in the space (the opening 11r) separated by the partition (11), color conversion layers (20) that convert a color of light emitted from the plurality of light-emitting elements (41). According to the configuration, effects similar to those in the first aspect can be exhibited.

In the method for manufacturing a display device according to an eighth aspect of the present disclosure, in the seventh aspect, a material having metallic luster may be used as the partition. According to the configuration, effects similar to those in the second aspect can be exhibited.

In the seventh or eighth aspect, the method for manufacturing a display device according to a ninth aspect of the present disclosure may include
a connecting step of electrically connecting a substrate (the mounting substrate 31) on which the plurality of light-emitting elements (41) electrically connected to the partition are arranged and the partition (11), the substrate being electrically connected to the plurality of light-emitting elements. According to the configuration, effects similar to those in the third aspect can be exhibited.

In the seventh or eighth aspect, the method for manufacturing a display device according to a tenth aspect of the present disclosure may include a step of forming a conductive film contacting with at least a part of a surface of the partition, and a connecting step of electrically connecting a substrate on which the plurality of light-emitting elements electrically connected to the conductive film are arranged and the conductive film, the substrate being electrically connected to the plurality of light-emitting elements. According to the configuration, effects similar to those in the fourth aspect can be exhibited.

The disclosure is not limited to each of the above-described embodiments. It is possible to make various modifications within the scope of the claims. An embodiment obtained by appropriately combining technical elements each disclosed in different embodiments falls also within the technical scope of the disclosure. Furthermore, technical elements disclosed in the respective embodiments may be combined to provide a new technical feature.

While there have been described what are at present considered to be certain embodiments of the invention, it will be understood that various modifications may be made thereto, and it is intended that the appended claims cover all such modifications as fall within the true spirit and scope of the invention.

What is claimed is:

1. A display device, comprising:
a plurality of light-emitting elements;
color conversion layers configured to convert a color of light emitted from the plurality of light-emitting elements; and
a partition configured to separate a region provided with each of the color conversion layers,
wherein the partition is formed of an inorganic material having a light-shielding property.

2. The display device according to claim 1,
wherein the partition is formed of a material having metallic luster.

3. The display device according to claim 1,
wherein the partition is formed of a material having conductivity,
the plurality of light-emitting elements are provided above a substrate, the plurality of light-emitting elements being electrically connected to the substrate and the partition, and
the partition is electrically connected to the substrate.

4. The display device according to claim 1,
wherein a conductive film is formed on at least a part of a surface of the partition,
the plurality of light-emitting elements are provided above a substrate, the plurality of light-emitting elements being electrically connected to the substrate and the conductive film, and
the conductive film is electrically connected to the substrate.

5. The display device according to claim 1, comprising:
a transparent layer formed of an inorganic material between the plurality of light-emitting elements and the color conversion layers.

6. The display device according to claim 1,
wherein slits are formed in the partition, the slits being configured to connect adjacent ones of the color conversion layers, or connect the color conversion layers and an outer edge of the partition.

7. A method for manufacturing a display device, comprising:
a partition providing step of providing, in a display device emitting monochrome light and in which a plurality of light-emitting elements are arranged, a space separated by a partition formed of an inorganic material having a light-shielding property, to substantially match an arrangement of each of the plurality of light-emitting elements; and
a color conversion layer providing step of providing, in the space separated by the partition, color conversion layers configured to convert a color of light emitted from the plurality of light-emitting elements.

8. The method for manufacturing a display device according to claim 7,
wherein a material having metallic luster is used as the partition.

9. The method for manufacturing a display device according to claim 7,
wherein the partition is formed of a material having conductivity, and
the method comprises a connecting step of electrically connecting a substrate on which the plurality of light-emitting elements electrically connected to the partition are arranged and the partition, the substrate being electrically connected to the plurality of light-emitting elements.

10. The method for manufacturing a display device according to claim 7, comprising:
a step of forming a conductive film contacting with at least a part of a surface of the partition; and
a connecting step of electrically connecting a substrate on which the plurality of light-emitting elements electrically connected to the conductive film are arranged and the conductive film, the substrate being electrically connected to the plurality of light-emitting elements.
